(19) United States
(12) Patent Application Publication
(10) Pub. No.: US 2026/0247825 A1
(43) Pub. Date: Aug. 20, 2026

(54) DISPLAY PANEL AND ELECTRONIC DEVICE INCLUDING THE SAME

(71) Applicant: Samsung Display Co., Ltd., Yongin-si (KR)

(72) Inventor: Guanghai Jin, Yongin-si (KR)

(21) Appl. No.: 19/309,274

(22) Filed: Aug. 25, 2025

(30) Foreign Application Priority Data
Feb. 14, 2025 (KR) 10-2025-0019659

(51) Int. Cl. H10K 59/35

(52) U.S. Cl. CPC H10K 59/353

(57) ABSTRACT

Provided are a display panel having an efficient pixel array structure, and an electronic device including the display panel. The display panel includes a first pixel group driven to correspond to a first dot on a screen, the first pixel group including a first subpixel, a second pixel group driven to correspond to a second dot on the screen, the second pixel group sharing the first subpixel with the first pixel group, a third pixel group driven to correspond to a third dot on the screen, the third pixel group sharing the first subpixel with the first pixel group and the second pixel group, and a first transmission portion surrounded by the first through third pixel groups.

### CROSS-REFERENCE TO RELATED APPLICATION

This application is based on and claims priority under 35 U.S.C. § 119 to Korean Patent Application No. 10-2025-0019659, filed on Feb. 14, 2025, in the Korean Intellectual Property Office, the disclosure of which is incorporated by reference herein in its entirety.

### BACKGROUND

### 1. Field

One or more embodiments relate to display panels and electronic devices including the same, and more particularly, to a display panel having an efficient pixel layout structure, and an electronic device including the display panel.

### 2. Description of the Related Art

Display panels may receive information about an image and display the image. Display panels are used as displays of small products, such as mobile phones, or are used as displays of large products, such as televisions.

Display panels include a plurality of pixels that receive electrical signals and emit light in order to display an image to the outside. Each of the plurality of pixels may include a light-emitting device. For example, organic light-emitting display apparatuses may include an organic light-emitting diode as a light-emitting device. In general, display panels may include thin film transistors and organic light-emitting diodes on a substrate.

Electronic devices may provide a user with a necessary visual interface through a display panel.

### SUMMARY

One or more embodiments include a display panel having an efficient pixel layout structure, and an electronic device including the display panel. However, aspects of embodiments are not limited thereto, and the above characteristics do not limit the scope of embodiments according to the disclosure.

Additional aspects will be set forth in portion in the description which follows and, in part, will be apparent from the description, or may be learned by practice of the presented embodiments of the disclosure.

According to one or more embodiments, a display panel including a plurality of subpixels arranged on a substrate includes a first pixel group driven to correspond to a first dot on a screen, the first pixel group including a first common subpixel, a second pixel group driven to correspond to a second dot on the screen, the second pixel group sharing the first common subpixel with the first pixel group, a third pixel group driven to correspond to a third dot on the screen, the third pixel group sharing the first common subpixel with the first pixel group and the second pixel group, and a first transmission portion surrounded by the first through third pixel groups. The first through third pixel groups are arranged to extend radially from the first common subpixel, the first pixel group and the second pixel group are arranged to overlap a first virtual polygon, the third pixel group is disposed to overlap a second virtual polygon adjacent to the first virtual polygon, and the first transmission portion is disposed within the first virtual polygon.

When the first pixel group is turned on, the first common subpixel may emit light based on a first control command for controlling the first pixel group.

When the first pixel group and the second pixel group are turned on, the first common subpixel may emit light, based on the first control command for controlling the first pixel group and a second control command for controlling the second pixel group.

When the first through third pixel groups are turned on, the first common subpixel may emit light, based on the first control command for controlling the first pixel group, the second control command for controlling the second pixel group, and a third control command for controlling the third pixel group.

The first pixel group may include a first auxiliary subpixel that generates light of a first wavelength, a second auxiliary subpixel that generates light of a second wavelength, and a third auxiliary subpixel that generates light of a third wavelength, and the first common subpixel may be the first auxiliary subpixel. In a plan view, an area of the first auxiliary subpixel may be greater than an area of the second auxiliary subpixel and an area of the third auxiliary subpixel, and the area of the second auxiliary subpixel may be less than the area of the third auxiliary subpixel.

In a plan view, the first auxiliary subpixel and the third auxiliary subpixel may be polygonal. The second auxiliary subpixel may be a trapezoid having an upper side and a lower side longer than the upper side. The upper side may be disposed to face the third auxiliary subpixel, and the upper side may be disposed to face the first auxiliary subpixel.

A center of gravity of each of the first through third auxiliary subpixels may be disposed to overlap a virtual line segment that forms the first virtual polygon.

The center of gravity of the second auxiliary subpixel and the center of gravity of the third auxiliary subpixel may be arranged to overlap vertexes of the first virtual polygon.

According to one or more embodiments, a display panel including a plurality of subpixels arranged on a substrate includes a first pixel group driven to correspond to a first dot on a screen, disposed to overlap a first virtual polygon, and including a first common subpixel, a second pixel group driven to correspond to a second dot on the screen, disposed to overlap the first virtual polygon, and sharing the first common subpixel with the first pixel group, a third pixel group driven to correspond to a third dot on the screen, disposed to overlap a second virtual polygon adjacent to the first virtual polygon, and sharing the first common subpixel with the first pixel group and the second pixel group, a fourth pixel group disposed within the first virtual polygon, driven to correspond to a fourth dot on the screen, and including a second common subpixel, a fifth pixel group disposed within the first virtual polygon, driven to correspond to a fifth dot on the screen, and sharing the second common subpixel, and a sixth pixel group disposed within the first virtual polygon, driven to correspond to a sixth dot on the screen, and sharing the second common subpixel, wherein the first through third pixel groups are arranged to extend radially from the first common subpixel, and the fourth through sixth pixel groups are arranged to extend radially from the second common subpixel.

The display panel may further include a first transmission portion disposed within the first virtual polygon and surrounded by the first pixel group, the second pixel group, the fourth pixel group, and the fifth pixel group.

When the first pixel group is turned on, the first common subpixel may emit light based on a first control command for controlling the first pixel group.

When the first pixel group and the second pixel group are turned on, the first common subpixel may emit light, based on the first control command for controlling the first pixel group and a second control command for controlling the second pixel group.

When the first through third pixel groups are turned on, the first common subpixel may emit light, based on the first control command for controlling the first pixel group, the second control command for controlling the second pixel group, and a third control command for controlling the third pixel group.

When the fourth pixel group is turned on, the second common subpixel may emit light, based on a fourth control command for controlling the fourth pixel group.

When the fourth pixel group and the fifth pixel group are turned on, the second common subpixel may emit light, based on the fourth control command for controlling the fourth pixel group and a fifth control command for controlling the fifth pixel group.

When the fourth through sixth pixel groups are turned on, the second common subpixel may emit light, based on the fourth control command for controlling the fourth pixel group, the fifth control command for controlling the fifth pixel group, and a sixth control command for controlling the sixth pixel group.

The first pixel group may include a first auxiliary subpixel that generates light of a first wavelength, a second auxiliary subpixel that generates light of a second wavelength, and a third auxiliary subpixel that generates light of a third wavelength, and the first common subpixel may be the first auxiliary subpixel. In a plan view, an area of the first auxiliary subpixel may be greater than an area of the second auxiliary subpixel and an area of the third auxiliary subpixel, and the area of the second auxiliary subpixel may be less than the area of the third auxiliary subpixel.

A center of gravity of each of the first through third auxiliary subpixels may be disposed to overlap a virtual line segment that forms the first virtual polygon.

The center of gravity of the second auxiliary subpixel and the center of gravity of the third auxiliary subpixel may be arranged to overlap vertexes of the first virtual polygon.

According to one or more embodiments, an electronic device includes memory storing data information, a processor configured to generate a data signal and/or a control signal, based on the data information, and one of the above-described display panels each operating based on the data signal and/or the control signal.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display panel according to an embodiment;

FIG. 2 is a schematic plan view of a display panel according to an embodiment;

FIG. 3 is a schematic cross-sectional view of the display panel taken along line A-A′ of FIG. 1;

FIG. 4 shows schematic cross-sectional views of the display panel respectively taken along lines I-I′ and II-II′ of FIG. 1;

FIGS. 5 and 6 are plan views of the display panel, schematically showing a subpixel pattern of a first display area of FIG. 1;

FIG. 7 is a plan view of the display panel, schematically showing an auxiliary subpixel pattern of a second display area of FIG. 1;

FIG. 8 is a plan view of the display panel, schematically showing an auxiliary subpixel pattern of the second display area of FIG. 1;

FIG. 9 is a plan view of the display panel, schematically showing an auxiliary subpixel pattern of the second display area of FIG. 1;

FIG. 10 is a plan view of the display panel, schematically showing an auxiliary subpixel pattern of the second display area of FIG. 1;

FIG. 11 is a plan view of the display panel, schematically showing an auxiliary subpixel pattern of the second display area of FIG. 1;

FIG. 12 is a plan view of the display panel, schematically showing an auxiliary subpixel pattern of the second display area of FIG. 1;

FIG. 13 is a plan view of the display panel, schematically showing an auxiliary subpixel pattern of the second display area of FIG. 1;

FIG. 14 is a plan view of the display panel, schematically showing an auxiliary subpixel pattern of the second display area of FIG. 1;

FIG. 15 is a plan view of the display panel, schematically showing an auxiliary subpixel pattern of the second display area of FIG. 1;

FIG. 16 is a plan view of the display panel, schematically showing an auxiliary subpixel pattern of the second display area of FIG. 1;

FIG. 17 is a plan view of the display panel, schematically showing an auxiliary subpixel pattern of the second display area of FIG. 1;

FIG. 18 is a plan view of the display panel, schematically showing an auxiliary subpixel pattern of the second display area of FIG. 1;

FIG. 19 is a plan view of the display panel, schematically showing an auxiliary subpixel pattern of the second display area of FIG. 1;

FIG. 20 is a plan view of the display panel, schematically showing an auxiliary subpixel pattern of the second display area of FIG. 1;

FIG. 21 is a plan view of the display panel, schematically showing an auxiliary subpixel pattern of the second display area of FIG. 1;

FIG. 22 is a plan view of the display panel, schematically showing an auxiliary subpixel pattern of the second display area of FIG. 1;

FIG. 23 is a plan view of the display panel, schematically showing an auxiliary subpixel pattern of the second display are of FIG. 1;

FIG. 24 is a plan view of the display panel, schematically showing an auxiliary subpixel pattern of the second display area of FIG. 1;

FIG. 25 is a plan view of the display panel, schematically showing an auxiliary subpixel pattern of the second display area of FIG. 1;

FIG. 26 is a plan view of the display panel, schematically showing an auxiliary subpixel pattern of the second display area of FIG. 1;

FIG. 27 is a plan view of the display panel, schematically showing an auxiliary subpixel pattern of the second display area of FIG. 1;

FIGS. 28 and 29 are plan views of the display panel, schematically showing auxiliary subpixel patterns of the second display area of FIG. 1;

FIGS. 30 through 34 are plan views of the display panel, schematically showing auxiliary subpixel patterns of the second display area of FIG. 1;

FIGS. 35 and 36 are plan views of the display panel, schematically showing auxiliary subpixel patterns of the second display area of FIG. 1;

FIG. 37 is a block diagram of an electronic device according to an embodiment; and

FIG. 38 illustrates schematic diagrams of electronic devices according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not be construed as limited to the embodiments set forth herein.

One or more embodiments will be described below in more detail with reference to the accompanying drawings. Those components that are the same as or are in correspondence with each other are rendered the same reference numeral regardless of the figure number, and redundant explanations are omitted.

It will be understood that although the terms “first,” “second,” etc. may be used herein to describe various components, these components should not be limited by these terms. These components are only used to distinguish one component from another. As used herein, the singular forms “a,” “an,” and “the” are intended to include the plural forms as well, unless the context clearly indicates otherwise.

It will be understood that, unless otherwise specified, when an element such as a layer, film, region, or substrate is referred to as being “on” another element, it can be “directly” on the other element or intervening elements may also be present.

In the drawings, the thicknesses of layers and regions are exaggerated or reduced for convenience of explanation. For example, since sizes and thicknesses of components in the drawings are arbitrarily illustrated for convenience of explanation, embodiments are not limited thereto.

The terms “comprises” and/or “comprising” used herein specify the presence of stated features or components, but do not preclude the presence or addition of one or more other features or components.

It will be understood that when a layer, region, or component is referred to as being “formed on” another layer, region, or component, it can be directly or indirectly formed on the other layer, region, or component. That is, for example, intervening layers, regions, or components may be present.

When a certain embodiment may be implemented differently, a specific process order may be performed differently from the described order. For example, two consecutively described processes may be performed substantially at the same time or performed in an order opposite to the described order.

In the present specification, “A and/or B” represents A or B, or A and B. The expression “at least one of A and B” indicates only A, only B, both A and B, or variations thereof.

It will also be understood that when a layer, region, or component is referred to as being “connected” or “coupled” to another layer, region, or component, it can be directly connected or coupled to the other layer, region, or/and component or intervening layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present.

In the following examples, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

A display panel according to an embodiment will now be described in detail based on the above-described matters.

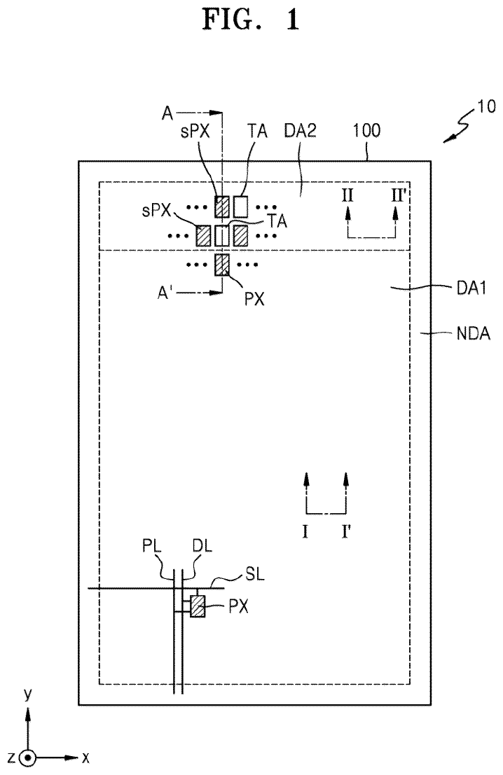

FIG. 1 is a schematic plan view of a display panel 10 according to an embodiment.

Referring to FIG. 1, the display panel 10 includes a first display area DA1 where an image is realized, and a non-display area NDA where no images are realized. The display panel may provide a main image by using light emitted by a plurality of subpixels PX arranged in the first display area DA1.

Each of the subpixels PX may include a display device such as an organic light-emitting device. Each of the subpixels PX may emit, for example, red light, green light, or blue light. The subpixel PX may be connected to a pixel circuit including a thin film transistor (TFT), a storage capacitor, etc. Such a pixel circuit may be connected to, for example, a scan line SL configured to transmit a scan signal, a data line DL configured to intersect the scan line SL and transmit a data signal, and a driving voltage line PL configured to supply a driving voltage. For example, the data line DL and the driving voltage line PL may each extend in a y direction (hereinafter, a second direction), and the scan line SL may extend in an x direction (hereinafter, a first direction).

The subpixel PX may emit light having a luminance corresponding to an electrical signal received from the data line DL. The display area DA may display a certain image by using light emitted by the subpixel PX. For reference, the subpixel PX used herein may be defined as a light-emission area that emits one of red light, green light, and blue light.

The display panel 10 may include a second display area DA2. The second display area DA2 may be an area underneath which a component such as a sensor using infrared light, visible light, or sound is arranged, as will be described later. The second display area DA2 may include a transmission portion TA capable of transmitting light or/and sound that is output from a component to the outside or travels from the outside toward the component. According to an embodiment, when light is transmitted through the second display area DA2, a light transmittance in the second display area DA2 may be about 30% or greater, for example, 50% or greater, 75% or greater, 80% or greater, 85% or greater, or 90% or greater.

According to the present embodiment, a plurality of auxiliary subpixels sPX may be arranged in the second display area DA2, and a certain image may be provided using light emitted by the plurality of auxiliary subpixels sPX. An image provided by the second display area DA2 is an auxiliary image and thus may have lower resolution than an image provided by the first display area DA1. In other words, because the second display area DA2 includes the transmission portion TA capable of transmitting light or/and sound, the number of auxiliary subpixels sPX arranged on a unit area may be less than the number of subpixels PX arranged on a unit area in the first display area DA1.

The second display area DA2 may be arranged on one side of the first display area DA1. In FIG. 1, the second display area DA2 is disposed on an upper side of the first display area DA1, and thus the second display area DA2 is disposed between the non-display area NDA and the first display area DA1. However, embodiments are not limited thereto. Various modifications may be made to the second display area DA2, for example, the second display area DA2 may be surrounded by the first display area DA1.

Although an organic light-emitting display panel will now be illustrated and described as the display panel 10 according to an embodiment, display panels according to embodiments are not limited thereto. According to another embodiment, various types of display panels, such as an inorganic light-emitting display panel and a quantum dot light-emitting display panel, may be used.

Although the second display area DA2 is disposed on the upper side of the first display area DA1 having a rectangular shape in FIG. 1, embodiments are not limited thereto. For example, the shape of the first display area DA1 may be a circle, an ellipse, or a polygon such as a triangle or pentagon. For example, the second display area DA2 may be disposed inside the first display area DA1, and may be provided in various shapes.

The non-display area NDA, which is an area where no subpixels PX and no auxiliary subpixels sPX are arranged, may be an area where no images are displayed. In the non-display area NDA, power supply wiring for driving the subpixels PX and the auxiliary subpixels sPX may be arranged. In addition, pads may be arranged in the non-display area NDA, and an integrated circuit device, such as a driver integrated circuit (IC) or a printed circuit board including a driving circuit unit, and the pads may be electrically connected to each other in the non-display area NDA.

For example, the non-display area NDA may be disposed outside the first display area DA1 and the second display area DA2, and the non-display area NDA may surround the first display area DA1 and the second display area DA2.

For reference, because the display panel 10 includes a substrate 100, it may be considered that the substrate 100 has the first display area DA1, the second display area DA2, and the non-display area NDA. A detailed description of the substrate 100 will be provided later.

A plurality of transistors may be arranged in the first display area DA1 and the second display area DA2. In the plurality of transistors, a first terminal of the transistor may be a source electrode or a drain electrode, and a second terminal thereof may be an electrode different from the first terminal, among the source electrode or the drain electrode, according to the type (N-type or P-type) and/or an operating condition of the transistor. For example, when the first terminal is a source electrode, the second terminal may be a drain electrode.

For convenience of explanation, each of the subpixel PX, the auxiliary subpixel sPX, and the transmission portion TA in FIG. 1 is illustrated as having a rectangular shape; however, the shape of each of the auxiliary subpixel sPX and the transmission portion TA is not limited thereto and may be modified in various ways. In addition, the subpixel PX, the auxiliary subpixel sPX, and the transmission portion TA in FIG. 1 are arranged side by side; however, the arrangement of the subpixel PX, the auxiliary subpixel sPX, and the transmission portion TA is not limited thereto, and may be modified in various ways.

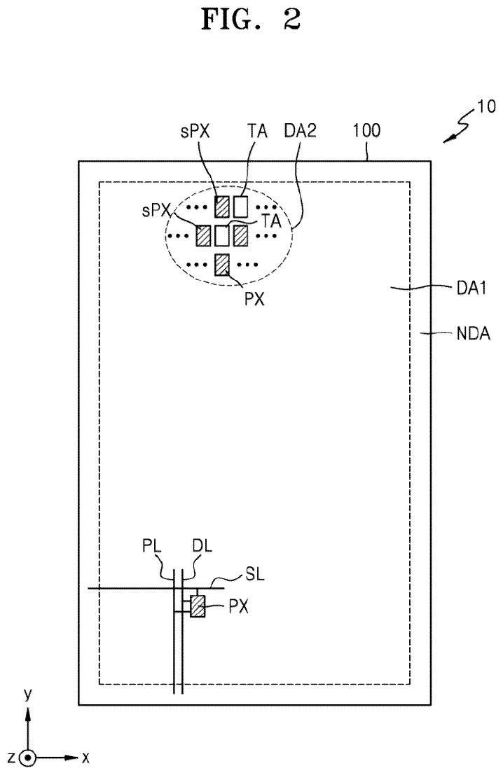

FIG. 2 is a schematic plan view of the display panel 10 according to an embodiment. For reference, in the description of FIG. 2, the same description as that provided above with reference to FIG. 1 may be omitted.

Although the second display area DA2 is arranged on one side of the first display area DA1 in FIG. 1, embodiments are not limited thereto. For example, as shown in FIG. 2, the second display area DA2 may be included as an area corresponding to a sensor or the like arranged underneath the second display area DA2. In this case, the second display area DA2 may be arranged inside the first display area DA1 and may be surrounded by the first display area DA1.

For convenience of explanation, each of the subpixel PX, the auxiliary subpixel sPX, and the transmission portion TA in FIG. 2 is illustrated as having a rectangular shape; however, the shape of each of the subpixel PX, auxiliary subpixel sPX, and the transmission portion TA is not limited thereto and may be modified in various ways. In addition, the auxiliary subpixel sPX and the transmission portion TA in FIG. 2 are arranged side by side; however, the arrangement of the auxiliary subpixel sPX and the transmission portion TA is not limited thereto, and may be modified in various ways.

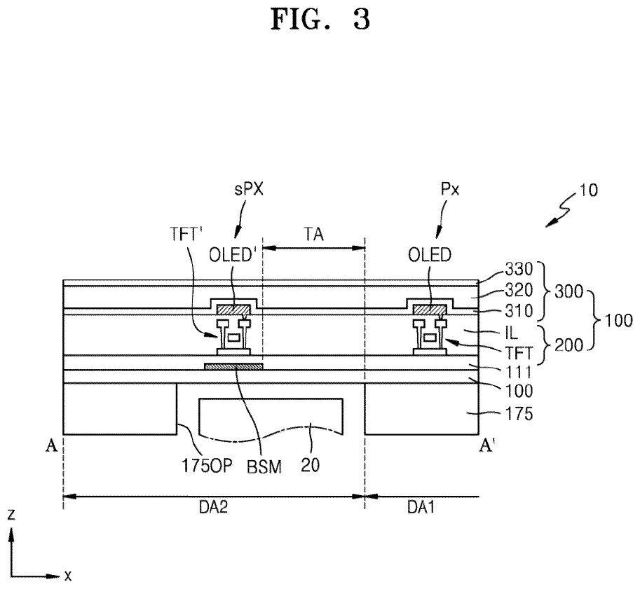

FIG. 3 may correspond to a schematic cross-section of the display panel 10 taken along line A-A′ of FIG. 1.

For reference, the schematic cross-sectional view along the line A-A′ of FIG. 1 shows a cross-sectional view of one subpixel PX, one transmission portion TA, and one auxiliary subpixel sPX, and may be a schematic cross-sectional view obtained based on a boundary between the first display area DA1 and the second display area DA2 for convenience of explanation. Accordingly, the schematic cross-sectional view of FIG. 3 may also be understood as a schematic cross-sectional view obtained based on the boundary between the first display area DA1 and the second display area DA2 in FIG. 2.

As shown in FIG. 3, a component 20 corresponding to the second display area DA2 may be disposed below the display panel 10.

The display panel 10 may include a substrate 100, a display element layer 200 disposed on the substrate 100, and a thin-film encapsulation layer 300 being an encapsulation member that seals the display element layer 200. The display panel 10 may further include a lower protection film 175 arranged below the substrate 100.

The substrate 100 may include glass or polymer resin. Examples of the polymer resin may include polyethersulfone, polyacrylate, polyetherimide, polyethylene naphthalate, polyethylene terephthalate, polyphenylene sulfide, polyarylate, polyimide, polycarbonate, and cellulose acetate propionate. The substrate 100 including polymer resin may have flexible, rollable, or bendable characteristics. The substrate 100 may have a multi-layered structure including a layer including the aforementioned polymer resin and an inorganic layer (not shown).

The display element layer 200 may include a circuit layer including first and second thin-film transistors TFT and TFT′, main and auxiliary organic light-emitting diodes OLED and OLED′ being display elements, and inorganic insulating layers IL therebetween.

In the first display area DA1, a subpixel PX including the first thin-film transistor TFT and the main organic light-emitting diode OLED connected to the first thin-film transistor TFT may be arranged. In the second display area DA2, an auxiliary subpixel sPX including the second thin-film transistor TFT′ and the auxiliary organic light-emitting diode OLED′ connected to the second thin-film transistor TFT′ may be arranged.

In the second display area DA2, the transmission portion TA having no display elements arranged therein may be arranged. The transmission portion TA may be understood as a transmission area that transmits light/signals emitted by the component 20 or light/signals incident upon the component 20.

The component 20 may be located in the second display area DA2. The component 20 may be an electronic element that uses light or sound. For example, the component 20 may be a sensor that receives and uses light, like an infrared sensor, a sensor that outputs and senses light or sound to measure a distance or recognize a fingerprint or the like, a small lamp that outputs light, or a speaker that outputs sound. An electronic element using light may use light in various wavelength bands, such as visible light, infrared light, and ultraviolet light. A plurality of components 20 may be arranged in the second display area DA2. For example, a light-emitting device and a light-receiving device as the component 20 may be both included in a single second display area DA2. Alternatively, both a light-emitting portion and a light-receiving portion may be included in a single component 20.

A lower electrode layer BSM may be arranged in the second display area DA2. The lower electrode layer BSM may be arranged to correspond to an area below the second thin-film transistor TFT′. The lower electrode layer BSM may prevent external light from reaching the auxiliary subpixel sPX including the second thin-film transistor TFT′ and the like. For example, the lower electrode layer BSM may prevent light emitted from the component 20 from reaching the auxiliary subpixel Pa.

According to an embodiment, a static voltage or a signal may be applied to the lower electrode layer BSM, and the lower electrode layer BSM, to which the static voltage or the signal has been applied, may prevent a pixel circuit from being damaged by electrostatic discharge.

The thin-film encapsulation layer 300 may include at least one inorganic encapsulation layer and at least one organic encapsulation layer. For example, the thin-film encapsulation layer 300 represents first and second inorganic encapsulation layers 310 and 330 and an organic encapsulation layer 320 therebetween.

The first and second inorganic encapsulation layers 310 and 330 may include at least one inorganic insulating material, such as aluminum oxide, titanium oxide, tantalum oxide, hafnium oxide, zinc oxide, silicon oxide, silicon nitride, silicon oxynitride, and/or the like. The organic encapsulation layer 320 may include a polymer-based material. Examples of the polymer-based material may include an acrylic resin, an epoxy-based resin, polyimide, and polyethylene.

The lower protective film 175 may be attached to a lower surface of the substrate 100 and may support and protect the substrate 100. The lower protection film 175 may include an opening 175OP corresponding to the second display area DA2. The lower protection film 175 may improve the light transmittance of the second display area DA2 by including the opening 175OP. The lower protection film 175 may include polyethylene terephthalate (PET) or polyimide (PI).

The second display area DA2 may have a larger area than an area where the component 20 is arranged. Accordingly, the area of the opening 175OP included in the lower protection film 175 may not be identical to the area of the second display area DA2. For example, the area of the opening 175OP may be less than the area of the second display area DA2.

Alternatively, a plurality of components 20 may be arranged in the second display area DA2. The plurality of components 20 may perform different functions. For example, one of the plurality of components 20 may be a camera, and the other may be an infrared sensor.

Although not shown, a component(s), such as an input sensing member for sensing a touch input, an anti-reflection member including a polarizer and a retarder, or a color filter and a black matrix, and a transparent window, may be arranged on the display panel 10.

According to the present embodiment, the thin-film encapsulation layer 300 is used as an encapsulation member that seals the display element layer 200, but embodiments are not limited thereto. For example, an encapsulation substrate coupled with the substrate 100 by a sealant or frit may be used as a member that seals the display element layer 200.

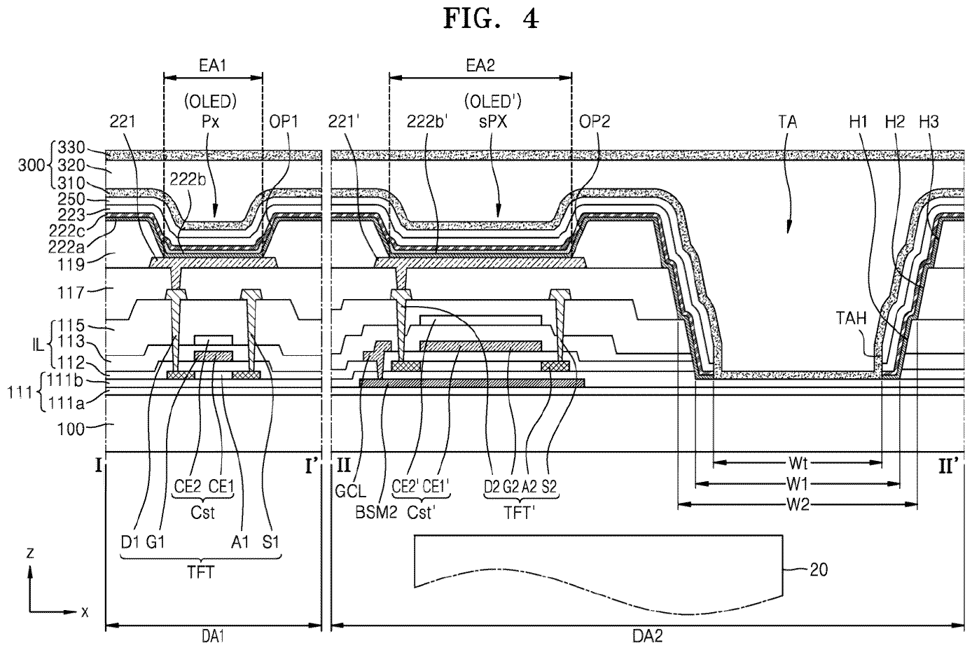

FIG. 4 shows schematic cross-sectional views of the display panel 10 respectively taken along lines I-I′ and II-II′ of FIG. 1.

For reference, at the level of ordinary skill in the art, the schematic cross-sectional view of FIG. 4 taken along the line I-I′ of FIG. 1 may be understood as a schematic cross-sectional view obtained from the first display area DA1 of FIG. 2, and the schematic cross-sectional view of FIG. 4 taken along the line II-II′ of FIG. 1 may be understood as a schematic cross-sectional view obtained from the second display area DA2 of FIG. 2.

As illustrated in FIG. 4, a subpixel PX may be arranged in the first display area DA1, and an auxiliary subpixel sPX and a transmission portion TA may be arranged in the second display area DA2.

For example, the subpixel PX may include the first thin-film transistor TFT, a main storage capacitor Cst, and the main organic light-emitting diode OLED. The auxiliary subpixel sPX may include the second thin-film transistor TFT′, an auxiliary storage capacitor Cst′, and the auxiliary organic light-emitting diode OLED′. The transmission portion TA may include an opening area TAH to correspond to the transmission portion TA.

Underneath the second display area DA2, the component 20 may be arranged. The component 20 may be a camera that captures an image, or an infrared (IR) sensor that transmits/receives IR light. Because the transmission portion TA is arranged in the second display area DA2, the transmission portion TA may transmit light that is transmitted/received to/from the component 20. For example, light emitted from the component 20 may travel via the transmission portion TA in a z direction, and light generated from outside the display apparatus and incident upon the component 20 may travel via the transmission portion TA in a-z direction. According to an embodiment, the component 20 may include a plurality of image sensors, and one image sensor may be arranged to correspond to one transmission portion TA.

A structure in which the components included in the display apparatus according to an embodiment are stacked will now be described.

The substrate 100 may include glass, a metal, or a polymer resin. The substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate.

The substrate 100 may have a multi-layered structure including two layers each including a polymer resin and a barrier layer including an inorganic material (silicon oxide, silicon nitride, silicon oxynitride, or the like) and located between the two layers. In this way, various modifications may be made.

The buffer layer 111 may be positioned on the substrate 100 and may reduce or prevent infiltration of a foreign material, moisture, or ambient air from below the substrate 100 and may provide a flat surface on the substrate 100. The buffer layer 111 may include an inorganic material (such as oxide or nitride), an organic material, or an organic and inorganic compound, and may be a single layer or multiple layers of an inorganic material and an organic material. A barrier layer (not shown) may be between the substrate 100 and the buffer layer 111 in order to prevent infiltration of ambient air. According to some embodiments, the buffer layer 111 may include silicon oxide (SiO₂) or silicon nitride (SiNX). For example, the buffer layer 111 may include a first buffer layer 111a and a second buffer layer 111b, one of which is stacked on the other.

In the second display area DA2, the lower electrode layer BSM may be between the first buffer layer 111a and the second buffer layer 111b. According to another embodiment, the lower electrode layer BSM may be between the substrate 100 and the first buffer layer 111a. The lower electrode layer BSM may be located below the second thin-film transistor TFT′ and may prevent characteristics of the second thin-film transistor TFT′ from degrading due to light emitted from, for example, the component 20.

The lower electrode layer BSM may be connected to a wire GCL arranged on a different layer, via a contact hole. The lower electrode layer BSM may receive a static voltage or a signal from the wire GCL. For example, the lower electrode layer BSM may receive a driving voltage ELVDD or a scan signal. As the lower electrode layer BSM receives a static voltage or a signal, the probability that electrostatic discharge occurs may be significantly reduced. The lower electrode layer BSM may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The lower electrode layer BSM may be a single layer or multi-layer including the aforementioned materials.

The first thin-film transistor TFT and/or the second thin-film transistor TFT′ may be arranged on the buffer layer 111. The first thin-film transistor TFT includes a first semiconductor layer A1, a first gate electrode G1, a first source electrode S1, and a first drain electrode D1, and the second thin-film transistor TFT′ includes a second semiconductor layer A2, a second gate electrode G2, a second source electrode S2, and a second drain electrode D2. The first thin-film transistor TFT may be connected to the main organic light-emitting diode OLED of the first display area DA1 and may drive the main organic light-emitting diode OLED. The second thin-film transistor TFT′ may be connected to the auxiliary organic light-emitting diode OLED′ of the second display area DA2 and may drive the auxiliary organic light-emitting diode OLED′.

The first semiconductor layer A1 and the second semiconductor layer A2 may be on the buffer layer 111 and may include polysilicon. According to another embodiment, the first semiconductor layer A1 and the second semiconductor layer A2 may include amorphous silicon. According to another embodiment, the first and second semiconductor layers A1 and A2 may include oxide of at least one selected from the group consisting of indium (In), gallium (Ga), tin (Sn), zirconium (Zr), vanadium (V), hafnium (Hf), cadmium (Cd), germanium (Ge), chromium (Cr), titanium (Ti), and zinc (Zn). The first and second semiconductor layers A1 and A2 may include a channel region, and a source region and a drain region doped with impurities.

The first semiconductor layer A1 may overlap the lower electrode layer BSM with the second buffer layer 111b therebetween. According to an embodiment, a width of the first semiconductor layer A1 may be less than a width of the lower electrode layer BSM. Accordingly, when projection is performed in a direction perpendicular to the substrate 100, the first semiconductor layer A1 may entirely overlap the lower electrode layer BSM.

The first gate insulating layer 112 may cover the first and second semiconductor layers A1 and A2. The first gate insulating layer 112 may include an inorganic insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The first gate insulating layer 112 may be a single layer or multi-layer including the aforementioned inorganic insulating materials.

The first gate electrode G1 and the second gate electrode G2 are located above the first gate insulating layer 112 to overlap the first semiconductor layer A1 and the second semiconductor layer A2, respectively. The first and second gate electrodes G1 and G2 may include molybdenum (Mo), aluminum (Al), copper (Cu), or titanium (Ti), and may each be a single layer or multiple layers. For example, the first and second gate electrodes G1 and G2 may each be a single Mo layer.

The second gate insulating layer 113 may cover the first gate electrode G1 and the second gate electrode G2. The second gate insulating layer 113 may include an inorganic insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The second gate insulating layer 113 may be a single layer or multi-layer including the aforementioned inorganic insulating materials.

A first upper electrode CE2 of the main storage capacitor Cst and a second upper electrode CE2′ of the auxiliary storage capacitor Cst′ may be arranged above the second gate insulating layer 113.

In the first display area DA1, the first upper electrode CE2 may overlap the first gate electrode G1. The first gate electrode G1 and the first upper electrode CE2 overlapping each other with the second gate insulating layer 113 therebetween may constitute the main storage capacitor Cst. The first gate electrode G1 may be the first lower electrode CE1 of the main storage capacitor Cst.

In the second display area DA2, the second upper electrode CE2′ may overlap the second gate electrode G2. The second gate electrode G2 and the second upper electrode CE2′ overlapping each other with the second gate insulating layer 113 therebetween may constitute the auxiliary storage capacitor Cst′. The first gate electrode G1 may be the second lower electrode CE1′ of the auxiliary storage capacitor Cst′.

The first and second upper electrodes CE2 and CE2′ may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may each be a single layer or multi-layer including the aforementioned materials.

The interlayer insulating layer 115 may cover the first upper electrode CE2 and the second upper electrode CE2′. The interlayer insulating layer 115 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like.

When the first gate insulating layer 112, the second gate insulating layer 113, and the interlayer insulating layer 115 are collectively referred to as an inorganic insulating layer IL, a structure in which the inorganic insulating layer IL is stacked on the substrate 100 may have a transmittance of about 90% or more with respect to an infrared wavelength. For example, light in a wavelength of 900 nm to 1,100 nm that pass through the substrate 100 and the inorganic insulating layer IL may have a transmittance of about 90%.

The first and second source electrodes S1 and S2 and the first and second drain electrodes D1 and D2 are on the interlayer insulating layer 115. Each of the first and second source electrodes S1 and S2 and the first and second drain electrodes D1 and D2 may include a conductive material including Mo, Al, Cu, and Ti, and may be a multi-layer or single layer including the aforementioned materials. For example, each of the first and second source electrodes S1 and S2 and the first and second drain electrodes D1 and D2 may be a multi-layer of Ti/Al/Ti.

The planarization layer 117 may cover the first and second source electrodes S1 and S2 and the first and second drain electrodes D1 and D2. The planarization layer 117 may have a flat upper surface such that a first pixel electrode 221 and a second pixel electrode 221′ that are located thereon are formed flat.

The planarization layer 117 may be a single layer including an organic material or a multi-layer formed by stacking single layers including an organic material. The planarization layer 117 may include a commercial polymer such as benzocyclobutene (BCB), polyimide, hexamethyldisiloxane (HMDSO), polymethyl methacrylate (PMMA) or polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, or the like.

An opening via which one of the first source electrode S1 and the first drain electrode D1 of the first thin-film-transistor TFT is exposed may be formed in the planarization layer 117, and the first pixel electrode 221 may contact the first source electrode S1 or the first drain electrode D1 via the opening and may be electrically connected to the first thin-film-transistor TFT.

Another opening via which one of the second source electrode S2 and the second drain electrode D2 of the second thin-film-transistor TFT′ is exposed may be formed in the planarization layer 117, and the second pixel electrode 221′ may contact the second source electrode S2 or the second drain electrode D2 via the opening and may be electrically connected to the second thin-film-transistor TFT′.

The first and second pixel electrodes 221 and 221′ may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). According to another embodiment, the first and second pixel electrodes 221 and 221′ may include a reflection layer including, for example, silver (Ag), magnesium (Mg), aluminum (Al), platinum (Pt), palladium (Pd), gold (Au), nickel (Ni), neodymium (Nd), iridium (Ir), chromium (Cr), or a compound of these materials. According to another embodiment, the first and second pixel electrodes 221 and 221′ may further include a film formed of ITO, IZO, ZnO, or In₂O₃ over/under the aforementioned reflection layer. According to an embodiment, each of the first and second pixel electrodes 221 and 221′ may have a stack structure of ITO/Ag/ITO.

A pixel-defining layer 119 may cover the edge of each of the first pixel electrode 221 and the second pixel electrode 221′. The pixel-defining layer 119 overlaps the first pixel electrode 221 and the second pixel electrode 221′, and includes a first opening OP1 and a second opening OP2 that define the light-emission areas of subpixels. The pixel-defining layer 119 may prevent an electric arc or the like from occurring on the edges of the first and second pixel electrodes 221 and 221′ by increasing distances between the edges of the first and second pixel electrodes 221 and 221′ and portions of an opposite electrode 223 on the first and second pixel electrodes 221 and 221′. The pixel-defining layer 119 may be formed of an organic insulating material, such as polyimide, polyamide, acryl resin, benzocyclobutene, hexamethyldisiloxane (HMDSO), or phenol resin, via spin coating or the like.

When the planarization layer 117 and the pixel-defining layer 119 are collectively referred to as an organic insulating layer, the organic insulating layer may have a transmittance of about 90% or more with respect to an infrared wavelength. For example, light in a wavelength of 900 nm to 1,100 nm that passes through the organic insulating layer may have a transmittance of about 90%.

A first emission layer 222b and a second emission layer 222b′ are arranged within the first opening OP1 and the second opening OP2 of the pixel-defining layer 119, respectively, to correspond to the first pixel electrode 221 and the second pixel electrode 221′, respectively. The first emission layer 222b and the second emission layer 222b′ may include a high molecular weight material or a low molecular weight material, and may emit red, green, blue, or white light.

An organic functional layer may be on and/or below the first emission layer 222b and the second emission layer 222b′. The organic functional layer 222e may include a first functional layer 222a and/or a second functional layer 222c. The first functional layer 222a or the second functional layer 222c may be omitted.

The first functional layer 222a may be below the first emission layer 222b and the second emission layer 222b′. The first functional layer 222a may be a single layer or multiple layers including an organic material. The first functional layer 222a may be a hole transport layer (HTL) having a single layer structure. Alternatively, the first functional layer 222a may include a hole injection layer (HIL) and an HTL. The first functional layer 222a may be integrally formed to correspond to the main subpixels Pm and the auxiliary subpixels Pa included in the first display area DA1 and the second display area DA2. Accordingly, the first functional layer 222a may be arranged to correspond to the transmission portion TA.

The second functional layer 222c may be above the first emission layer 222b and the second emission layer 222b′. The second functional layer 222c may be a single layer or multiple layers including an organic material. The second functional layer 222c may include an electron transport layer (ETL) and/or an electron injection layer (EIL). The second functional layer 222c may be integrally formed to correspond to the main subpixels Pm and the auxiliary subpixels Pa included in the first display area DA1 and the second display area DA2. Accordingly, the second functional layer 222c may be arranged to correspond to the transmission portion TA.

The opposite electrode 223 is arranged on the second functional layer 222c. The opposite electrode 223 may include a conductive material having a low work function. For example, the opposite electrode 223 may include a (semi)transparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of these materials. Alternatively, the opposite electrode 223 may further include a layer, such as ITO, IZO, ZnO, or In₂O₃, on the (semi)transparent layer including any of the above-described materials. The opposite electrode 223 may be integrally formed to correspond to the main subpixels PX and the auxiliary subpixels sPX included in the first display area DA1 and the second display area DA2.

The layers ranging from the first pixel electrode 221 to the opposite electrode 223 arranged in the first display area DA1 may constitute the main organic light-emitting diode OLED. The layers ranging from the second pixel electrode 221′ to the opposite electrode 223 arranged in the second display area DA2 may constitute the auxiliary organic light-emitting diode OLED′.

An upper layer 250 including an organic material may be formed on the opposite electrode 223. The upper layer 250 may be provided to protect the opposite electrode 223 and also increase light extraction efficiency. The upper layer 250 may include an organic material having a higher refractive index than the opposite electrode 223. Alternatively, the upper layer 250 may be a stack of layers having different refractive indexes. For example, the upper layer 250 may be provided by stacking a high refractive index layer, a low refractive index layer, and a high refractive index layer in this stated order. In this case, the high refractive index layer may have a refractive index of 1.7 or more, and the low refractive index layer may have a refractive index of 1.3 or less.

The upper layer 250 may additionally include lithium fluoride (LiF). Alternatively, the upper layer 250 may include an inorganic insulating material, such as silicon oxide (SiO₂) or silicon nitride (SiNx).

According to the present embodiment, the first functional layer 222a, the second functional layer 222c, the opposite electrode 223, and the upper layer 250 may include the opening area TAH corresponding to the transmission portion TA. In other words, the first functional layer 222a, the second functional layer 222c, the opposite electrode 223, and the upper layer 250 may include openings corresponding to the transmission portion TA, respectively. The respective openings of the first functional layer 222a, the second functional layer 222c, the opposite electrode 223, and the upper layer 250 may be formed by laser. According to an embodiment, the openings that form the opening area TAH may have substantially the same widths. For example, the width of the opening of the opposite electrode 223 may be substantially the same as that of the opening area TAH.

According to the present embodiment, the first functional layer 222a, the second functional layer 222c, and the upper layer 250 may be omitted. In this case, the opening of the opposite electrode 223 may be the opening area TAH.

That the opening area TAH corresponds to the transmission portion TA may mean the opening area TAH overlapping the transmission portion TA. In this case, the opening area TAH may have a smaller area than a first hole H1 formed in the inorganic insulating layer IL. To this end, FIG. 4 illustrates that a width Wt of the opening area TAH is less than a width W1 of the first hole H1. The area of the opening area TAH and the area of the first hole H1 may be defined as areas of narrowest openings.

According to an embodiment, the first functional layer 222a, the second functional layer 222c, the opposite electrode 223, and the upper layer 250 may be located on respective lateral surfaces of the first hole H1, a second hole H2, and a third hole H3. According to an embodiment, inclinations of the respective lateral surfaces of the first hole H1, the second hole H2, and the third hole H3 with respect to the upper surface of the substrate 100 may be more gentle than an inclination of the lateral surface of the opening area TAH with respect to the upper surface of the substrate 100.

Because the opening area TAH being formed means a member such as the opposite electrode 223 being removed from the transmission portion TA, the light transmittance in the transmission portion TA may significantly increase.

The main organic light-emitting diode OLED and the auxiliary organic light-emitting diode OLED′ may be sealed by the thin-film encapsulation layer 300. The thin-film encapsulation layer 300 may be located on the upper layer 250. The thin-film encapsulation layer 300 may prevent infiltration of external moisture or foreign materials into the main organic light-emitting diode OLED and the auxiliary organic light-emitting diode OLED′.

The thin-film encapsulation layer 300 may include at least one inorganic encapsulation layer and at least one organic encapsulation layer, and may have a structure in which a first inorganic encapsulation layer 310, an organic encapsulation layer 320, and a second inorganic encapsulation layer 330 are stacked. However, according to another embodiment, the number of organic encapsulation layers 320, the number of inorganic encapsulation layers 310 and 330, and the order in which organic encapsulation layers 320 and inorganic encapsulation layers 310 and 330 are stacked may be modified.

The first and second inorganic encapsulation layers 310 and 330 may include at least one inorganic insulating material, such as aluminum oxide, titanium oxide, tantalum oxide, hafnium oxide, zinc oxide, silicon oxide, silicon nitride, and silicon oxynitride, and may be formed via chemical vapor deposition (CVD) or the like. The organic encapsulation layer 320 may include a polymer-based material. Examples of the polymer-based material may include a silicon-based resin, an acryl-based resin, an epoxy-based resin, polyimide, and polyethylene.

The first inorganic encapsulation layer 310, the organic encapsulation layer 320, and the second inorganic encapsulation layer 330 may each be integrally provided to cover the display area DA and the second display area DA2. Accordingly, the first inorganic encapsulation layer 310, the organic encapsulation layer 320, and the second inorganic encapsulation layer 330 may be arranged within the opening area TAH.

For example, the organic encapsulation layer 320 may be integrally formed to cover the first display area DA1 and the second display area DA2, but may not exist in the transmission portion TA. In other words, the organic encapsulation layer 320 may include an opening corresponding to the transmission portion TA. In this case, the first inorganic encapsulation layer 310 and the second inorganic encapsulation layer 330 may contact each other within the transmission hole TAH.

For example, the second opening OP2 defining a light-emission area EA2 of the auxiliary subpixel sPX may have a larger size than the first opening OP1 defining a light-emission area EA1 of the subpixel PX. Accordingly, when the auxiliary subpixel sPX and the subpixel PX receive the same current, the auxiliary subpixel sPX may provide greater brightness than the subpixel PX.

Because the number of auxiliary subpixels sPX per unit area of the second display area DA2 is less than the number of auxiliary subpixels sPX per unit area of the first display area DA1, a luminance implemented per unit area of the first display area DA1 may be the same as a luminance implemented per unit area of the second display area DA2.

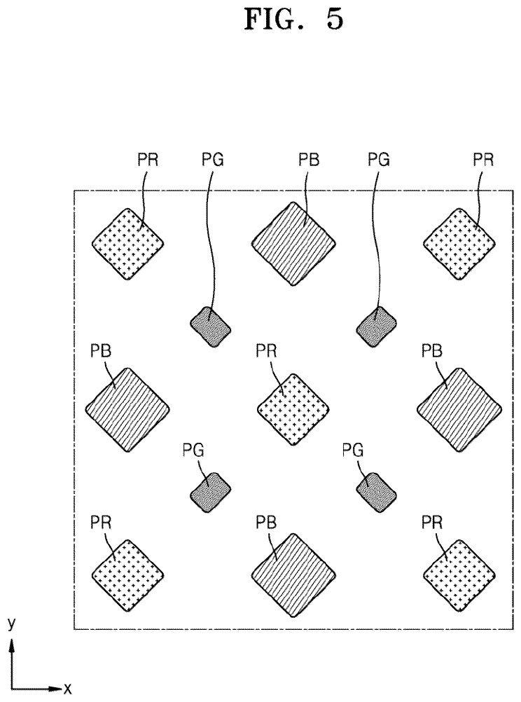

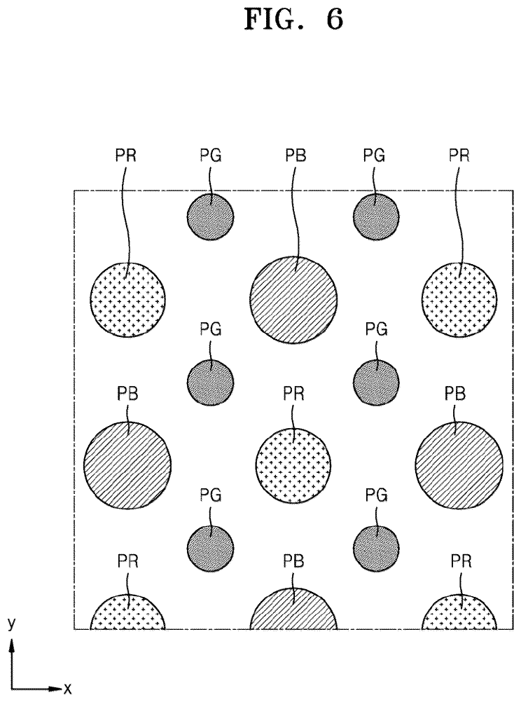

FIGS. 5 and 6 are plan views of the display panel 10, schematically showing a subpixel pattern of the first display area DA1 of FIG. 1.

The subpixel patterns in FIGS. 5 and 6 are merely examples, and various modified subpixel patterns may be formed in the first display area DA1 of FIG. 1.

For example, the subpixels of the first display area DA1 may include subpixels PB that emit a first wavelength band (for example, a wavelength band in a blue area of visible light), subpixels PG that emit a second wavelength band (for example, a wavelength band in a green area of visible light), and subpixels PR that emit a third wavelength band (for example, a wavelength band in a red area of visible light).

For example, respective shapes of the subpixels PB, PG, and PR in FIG. 5 may be approximately rectangular, and corners thereof may be rounded. For example, respective shapes of the subpixels PB, PG, and PR in FIG. 6 may be approximately circular.

For example, respective sizes of the subpixels PB, PG, and PR in FIGS. 5 and 6 may be different from each other. An area of the subpixel PB of the first wavelength band may be the largest, and an area of the subpixel PG of the second wavelength band may be the smallest. The size of the subpixel PR of the third wavelength band may be smaller than the size of the subpixel PB of the first wavelength band and may be larger than the size of the subpixel PG of the second wavelength band.

Hereinafter, in the disclosure, ‘sharing’ a specific element may mean that two or more elements commonly include the specific element. Two or more dots or pixel groups ‘sharing’ a specific subpixel may mean that the specific subpixel is involved in the driving of all of the two or more dots or pixel groups.

A plurality of auxiliary subpixels may be grouped into a pixel group, and the pixel group may be a unit element driven as one dot on the screen. For example, when one dot is turned on on the screen, it may mean that auxiliary subpixels defined as one pixel group corresponding to the turned-on dot (or at least one of the auxiliary subpixels defined as one pixel group) are turned on.

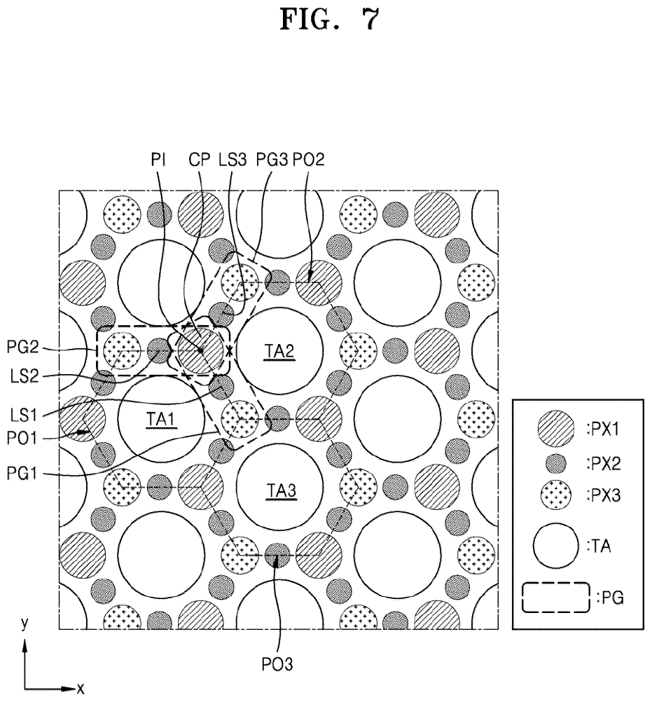

FIG. 7 is a plan view of the display panel 10, schematically showing an auxiliary subpixel pattern of the second display area DA2 of FIG. 1. For reference, in the description of FIG. 7, the same description as that provided above with reference to FIGS. 1 through 6 may be omitted.

A plurality of auxiliary subpixels and pixel groups may be defined as being arranged on the substrate 100. As shown in FIG. 7, in a plan view, virtual polygons and pixel groups may be arranged to overlap each other. Virtual line segments constituting a virtual polygon in a plan view may be arranged to overlap each other. For convenience of explanation, only some of the virtual polygons are shown in FIG. 7, but it is understood that the auxiliary subpixel pattern may be interpreted based on the virtual polygons even in areas where the virtual polygons are not explicitly illustrated.

For example, the auxiliary subpixels of the second display area DA2 may include first auxiliary subpixels PX1 that emit a first wavelength band (for example, a wavelength band in a blue area of visible light), second auxiliary subpixels PX2 that emit a second wavelength band (for example, a wavelength band in a green area of visible light), and third auxiliary subpixels PX3 that emit a third wavelength band (for example, a wavelength band in a red area of visible light). For example, the shapes of the auxiliary subpixels of the second display area DA2 in a plan view may be substantially circular.

A shared subpixel to be described below may not be a second auxiliary subpixel emitting a second wavelength band. The shared subpixel to be described below may be a first auxiliary subpixel emitting a first wavelength band or a third auxiliary subpixel emitting a third wavelength band, because reducing the number of second auxiliary subpixels that emit the second wavelength band, which is most sensitively recognized by the human eye, may result in a noticeable decrease in image quality. Therefore, it is necessary to utilize, as shared subpixels, auxiliary subpixels that emit wavelength bands that are relatively less sensitive to the human eye. When the first auxiliary subpixel emitting the first wavelength band, which is the least sensitively recognized by the human eye, is used as a shared subpixel that is to be described later, a user may least perceive a decrease in image quality even when the shared subpixel is utilized in dot display.

A first virtual polygon PO1 may be adjacent to a second virtual polygon PO2, and the first virtual polygon PO1 and the second virtual polygon PO2 may share a virtual line segment. The first virtual polygon PO1 may be adjacent to a third virtual polygon PO3, and the first virtual polygon PO1 and the third virtual polygon PO3 may share a virtual line segment. The third virtual polygon PO3 may be adjacent to the second virtual polygon PO2, and the third virtual polygon PO2 and the second virtual polygon PO2 may share a virtual line segment. For example, the first through third virtual polygons PO1 through PO3 may be regular hexagons. For example, when virtual polygons are regular hexagons, the virtual polygons may share adjacent sides with other adjacent virtual polygons. As another example, when the virtual polygons are regular hexagons, all of the pixel groups that overlap one virtual polygon, which is a regular hexagon, may become one dot.

For example, a first pixel group PG1 may be arranged on the substrate 100, and may be arranged to overlap a first virtual line segment LS1 forming the first virtual polygon PO1. The first pixel group PG1 may include at least three auxiliary subpixels. For example, the first pixel group PG1 may include one first auxiliary subpixel PX1, one second auxiliary subpixel PX2, and one third auxiliary subpixel PX3. For example, the first pixel group PG1 may be driven to correspond to a first dot on the screen and may include a common subpixel, and a first common subpixel CP may be the first auxiliary subpixel PX1.

For example, a second pixel group PG2 may be arranged on the substrate 100, and may be arranged to overlap a second virtual line segment LS2 forming the first virtual polygon PO1. The second virtual line segment LS2 and the first virtual line segment LS1 may share one vertex PI. The second pixel group PG2 may include at least three auxiliary subpixels. For example, the first pixel group PG1 may include one first auxiliary subpixel PX1, one second auxiliary subpixel PX2, and one third auxiliary subpixel PX3. For example, the second pixel group PG2 may be driven to correspond to a second dot on the screen, may include the first common subpixel CP, and may share the first common subpixel CP with the first pixel group PG1.

For example, a third pixel group PG3 may be arranged on the substrate 100, and may be arranged to overlap a third virtual line segment LS3 forming the second virtual polygon PO2. The third virtual line segment LS3, the first virtual line segment LS1, and the second virtual line segment LS2 may share one vertex PI. The third pixel group PG3 may include at least three auxiliary subpixels. For example, the third pixel group PG3 may include one first auxiliary subpixel PX1, one second auxiliary subpixel PX2, and one third auxiliary subpixel PX3. For example, the third pixel group PG3 may be driven to correspond to a third dot on the screen, may include the first common subpixel CP, and may share the first common subpixel CP with the first pixel group PG1 and the second pixel group PG2.

For example, the first common subpixel CP may be disposed to overlap the one vertex PI shared by the first virtual line segment LS1, the second virtual line segment LS2, and the third virtual line segment LS3. The first common subpixel CP may be the first auxiliary subpixel PX1 as described above, and a cross-sectional area of the first common subpixel CP may be greater than a cross-sectional area of the second auxiliary subpixel PX2 and a cross-sectional area of the third auxiliary subpixel PX3.

For example, the first through third pixel groups PG1 through PG3 may be arranged to extend radially from the first common subpixel CP, the first pixel group PG1 and the second pixel group PG2 may be arranged to overlap the first virtual polygon PO1, and the third pixel group PG3 may be arranged to overlap the second virtual polygon PO2 adjacent to the first virtual polygon PO1.

A first transmission portion TA1 may be placed within the first virtual polygon PO1. A plurality of auxiliary subpixels arranged to overlap virtual line segments forming the first virtual polygon PO1 may be arranged to surround the first transmission portion TA1 in a plan view. For example, the shape of the first transmission portion TA1 may be circular in a plan view. However, the shape of the first transmission portion TA1 is an example, and thus may be modified variously.

A second transmission portion TA2 may be placed within the second virtual polygon PO2. A plurality of auxiliary subpixels arranged to overlap virtual line segments forming the second virtual polygon PO2 may be arranged to surround the second transmission portion TA2 in a plan view. For example, the shape of the second transmission portion TA2 may be circular in a plan view. However, the shape of the second transmission portion TA2 is an example, and thus may be modified variously.

A third transmission portion TA3 may be placed within the third virtual polygon PO3. A plurality of auxiliary subpixels arranged to overlap virtual line segments forming the third virtual polygon PO3 may be arranged to surround the third transmission portion TA3 in a plan view. For example, the shape of the third transmission portion TA3 may be circular in a plan view. However, the shape of the third transmission portion TA3 is an example, and thus may be modified variously.

For example, virtual polygons including the first through third virtual polygons PO1 through PO3 may be hexagons. However, as will be described below, the virtual polygons may be of various shapes.

The first pixel group PG1 may include at least three auxiliary subpixels, and may include the first auxiliary subpixel PX1, the second auxiliary subpixel PX2, and the third auxiliary subpixel PX3 in this stated order. The first pixel group PG1 may share the first common subpixel CP with the second pixel group PG2 and the third pixel group PG3 described above. The vertex PI placed on one end of the first virtual line segment LS1, and the first common subpixel CP may overlap each other.

For example, a planar area of the first auxiliary subpixel PX1 may be greater than a planar area of the second auxiliary subpixel PX2, and may be greater than a planar area of the third auxiliary subpixel PX3. For example, the planar area of the second auxiliary subpixel PX2 may be less than the planar area of the third auxiliary subpixel PX3.

For example, a center of gravity of each of the first through third auxiliary subpixels PX 1, PX 2, and PX 3 may be arranged to overlap a virtual line segment forming the first virtual polygon. In this case, the center of gravity is the center of gravity of an area of an auxiliary subpixel that emits light on a plane, and may refer to the center of gravity obtained when it is assumed that a virtual plane having the same shape as the area that emits light has a uniform weight per unit area. For example, the center of gravity of the second auxiliary subpixel PX2 and the center of gravity of the third auxiliary subpixel PX3 may be arranged to overlap the vertex of the first virtual polygon, and the center of gravity of the first auxiliary subpixel PX1 may be located at the center of the virtual line segment. For example, the second auxiliary subpixel PX2 and the third auxiliary subpixel PX3 may be arranged alternately at six corners of a virtual polygon (regular hexagon). The first auxiliary subpixel PX1 may be disposed between the second auxiliary subpixel PX2 and the third auxiliary subpixel PX3.

For example, respective shapes of the first through third auxiliary subpixels PX 1, PX 2, and PX 3 may be circular. In another example, the shape of the second auxiliary subpixel PX may be elliptical.

A correlation between a method in which the first through third pixel groups PG1 through PG3 are driven and a method in which the first common subpixel CP is driven may be as follows. When one pixel group is turned on, this may refer to a case where all of the subpixels included in one pixel group are turned on.

For example, when the first pixel group PG1 is turned on, the first common subpixel CP may emit light based on a first control command for controlling the first pixel group PG1. For example, when the first pixel group PG1 and the second pixel group PG2 are turned on, the first common subpixel CP may emit light, based on the first control command for controlling the first pixel group PG1 and a second control command for controlling the second pixel group PG2. For example, when the first through third pixel groups PG1 through PG3 are turned on, the first common subpixel CP may emit light, based on the first control command for controlling the first pixel group PG1, the second control command for controlling the second pixel group PG2, and a third control command for controlling the third pixel group PG3.

For example, a control command used herein may refer to the intensity of a driving current. Alternatively, the control command may refer to an electrical signal sent from a driving circuit to drive a pixel group or an auxiliary subpixel included in the pixel group.

For example, when one pixel group among the first through third pixel groups PG1 through PG3 is turned on, the first common subpixel CP may emit light with a first brightness. Alternatively, when one pixel group among the first through third pixel groups PG1 through PG3 is turned on, a driving current with a first magnitude may flow in the first common subpixel CP.

For example, when two pixel groups among the first through third pixel groups PG1 through PG3 are turned on, the first common subpixel CP may emit light with a second brightness that is greater than the first brightness. Alternatively, when two pixel groups among the first through third pixel groups PG1 through PG3 are turned on, a driving current with a second magnitude greater than the first magnitude may flow in the first common subpixel CP. For example, the second magnitude may be twice the first magnitude.

For example, when three pixel groups among the first through third pixel groups PG1 through PG3 are turned on, the first common subpixel CP may emit light with a third brightness that is greater than the second brightness. Alternatively, when three pixel groups among the first through third pixel groups PG1 through PG3 are turned on, a driving current with a third magnitude greater than the second magnitude may flow in the first common subpixel CP. For example, the third magnitude may be triple the first magnitude.

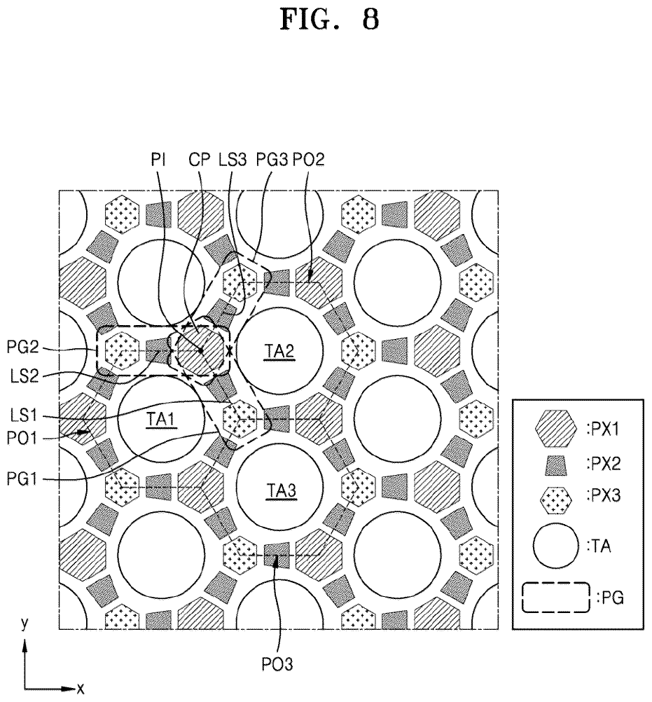

FIG. 8 is a plan view of the display panel 10, schematically showing an auxiliary subpixel pattern of the second display area DA2 of FIG. 1.

For reference, in the description of FIG. 8, the same description as that provided above with reference to FIGS. 1 through 7 may be omitted. A method in which pixel groups are driven and a correlation between the pixel groups and a common subpixel in FIG. 7 may be the same as the method in which the pixel groups are driven and the correlation between the pixel groups and the common subpixel in FIG. 7.

As shown in FIG. 8, the shape of the first auxiliary subpixel PX1 may be polygonal in a plan view. For example, the shape of the first auxiliary subpixel PX1 may be hexagonal in a plan view. When the shape of the first auxiliary subpixel PX1 is hexagonal, the corners of the hexagon may be sharp or rounded.

The shape of the second auxiliary subpixel PX2 may be polygonal in a plan view. For example, the shape of the second auxiliary subpixel PX2 may be trapezoidal in a plan view. When the shape of the second auxiliary subpixel PX2 is trapezoidal, the corners of the trapezoid may be sharpened or rounded. For example, the shape of the second auxiliary subpixel PX2 may be a trapezoid having a bottom side having a first length and an upper side having a second length that is less than the first length. In this case, the bottom side having the first length may be placed near the first auxiliary subpixel PX1, and the upper side having the second length may be placed near the third auxiliary subpixel PX3. For example, the bottom side having the first length greater than the second length may be placed near an auxiliary subpixel having a larger area among the first auxiliary subpixel PX1 and the third auxiliary subpixel PX3. For example, the upper side having a less length than the first length may be placed near an auxiliary subpixel having a smaller area among the first auxiliary subpixel PX1 and the third auxiliary subpixel PX3.

The shape of the third auxiliary subpixel PX3 may be polygonal in a plan view. For example, the shape of the third auxiliary subpixel PX3 may be hexagonal in a plan view. When the shape of the third auxiliary subpixel PX3 is hexagonal, the corners of the hexagon may be sharpened or rounded.

In a plan view, the area of the first auxiliary subpixel PX1 may be greater than the area of the second auxiliary subpixel PX2, and may be greater than the area of the third auxiliary subpixel PX3. In this case, the first auxiliary subpixel PX1 may be a subpixel emitting a first wavelength band (e.g., a blue visible light range) that is least sensitive to the human eye.

For example, unlike FIG. 8, the shapes of the first auxiliary subpixel PX1 and the third auxiliary subpixel PX3 may be modified differently. When the shape of the second auxiliary subpixel PX2 is trapezoidal, a bottom side having a greater length than an upper side may be placed near an auxiliary subpixel having a larger area among the first auxiliary subpixel PX1 and the third auxiliary subpixel PX3, and the upper side having a less length than the bottom side may be placed near an auxiliary subpixel having a smaller area among the first auxiliary subpixel PX1 and the third auxiliary subpixel PX3.

For example, one pixel group may include the first auxiliary subpixel PX1, the second auxiliary subpixel PX2, and the third auxiliary subpixel PX3 in this stated order. One pixel group may include auxiliary subpixels arranged to overlap a single virtual line segment forming a virtual polygon.

For example, the first pixel group PG1 may include the first common subpixel CP, and the first common subpixel CP may be the first auxiliary subpixel PX1. The second pixel group PG2 may include the first common subpixel CP, and may share the first common subpixel CP with the first pixel group PG1. The third pixel group PG3 may include the first common subpixel CP, and may share the first common subpixel CP with the first pixel group PG1 and the second pixel group PG2.

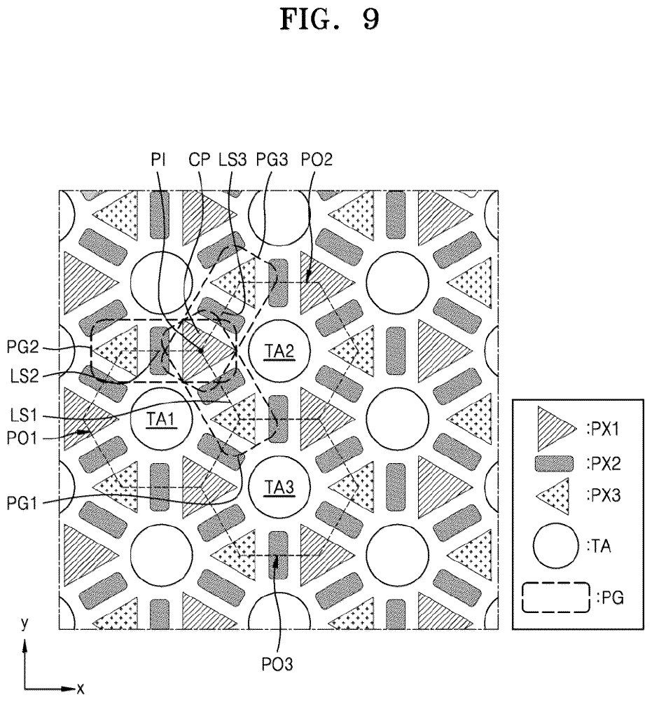

FIG. 9 is a plan view of the display panel 10, schematically showing an auxiliary subpixel pattern of the second display area DA2 of FIG. 1.

For reference, in the description of FIG. 9, the same description as that provided above with reference to FIGS. 1 through 8 may be omitted. A method in which pixel groups are driven and a correlation between the pixel groups and a common subpixel in FIG. 9 may be the same as the methods in which the pixel groups are driven and the correlations between the pixel groups and the common subpixel in FIGS. 7 and 8.

As shown in FIG. 9, the shape of the first auxiliary subpixel PX1 may be polygonal in a plan view. For example, the shape of the first auxiliary subpixel PX1 may be triangular in a plan view. When the shape of the first auxiliary subpixel PX1 is triangular, the corners of the triangle may be sharp or rounded.

For example, the first pixel group PG1 may include the first common subpixel CP, and the first common subpixel CP may be the first auxiliary subpixel PX1. The first through third pixel groups PG1 through PG3 may share the first common subpixel CP, and the first common subpixel CP may be arranged to overlap the vertex PI shared by the first, second, and third virtual line segments LS1, LS2, and LS3. Characteristics of the first through third pixel groups PG1 through PG3 are as described above with reference to FIGS. 7 and 8.

The shape of the second auxiliary subpixel PX2 may be polygonal in a plan view. For example, the shape of the second auxiliary subpixel PX2 may be quadrangular (or rectangular) in a plan view. When the shape of the second auxiliary subpixel PX2 is quadrangular (or rectangular), the corners of the quadrangle (or rectangle) may be sharpened or rounded. For example, when the shape of the second auxiliary subpixel PX2 is rectangular, the second auxiliary subpixel PX2 may be arranged between the first auxiliary subpixel PX1 and the third auxiliary subpixel PX3, a longer side of the second auxiliary subpixel PX2 may be arranged to be parallel to one side of the first auxiliary subpixel PX1 or the third auxiliary subpixel PX3, and a shorter side of the second auxiliary subpixel PX2 may be arranged near a transmission portion arranged inside a virtual polygon. For example, a lengthwise direction of the second auxiliary subpixel PX2 may be oriented toward the transmission portion arranged inside a virtual polygon most adjacent to the second auxiliary subpixel PX2.

The shape of the third auxiliary subpixel PX3 may be polygonal in a plan view. For example, the shape of the third auxiliary subpixel PX3 may be triangular in a plan view. When the shape of the third auxiliary subpixel PX3 is triangular, the corners of the triangle may be sharpened or rounded.

In a plan view, the area of the first auxiliary subpixel PX1 may be greater than the area of the second auxiliary subpixel PX2, and may be the same as or similar to the area of the third auxiliary subpixel PX3. In this case, the first auxiliary subpixel PX1 may be a subpixel emitting a first wavelength band (e.g., a blue visible light range) that is least sensitive to the human eye or a third wavelength band (e.g., a red visible light range).

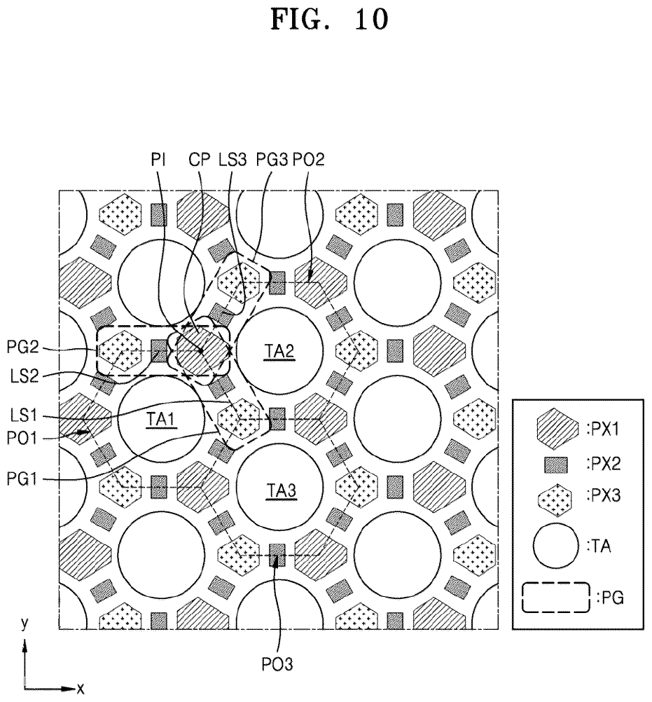

FIG. 10 is a plan view of the display panel 10, schematically showing an auxiliary subpixel pattern of the second display area DA2 of FIG. 1.

For reference, in the description of FIG. 10, the same description as that provided above with reference to FIGS. 1 through 9 may be omitted. A method in which pixel groups are driven and a correlation between the pixel groups and a common subpixel in FIG. 10 may be the same as the methods in which the pixel groups are driven and the correlations between the pixel groups and the common subpixel in FIGS. 7 through 9.

As shown in FIG. 10, the shape of the first auxiliary subpixel PX1 may be polygonal in a plan view. For example, the shape of the first auxiliary subpixel PX1 may be an irregular hexagon in a plan view. When the shape of the first auxiliary subpixel PX1 is an irregular hexagon, the corners of the irregular hexagon may be sharpened or rounded.

For example, the first pixel group PG1 may include the first common subpixel CP, and the first common subpixel CP may be the first auxiliary subpixel PX1. The first through third pixel groups PG1 through PG3 may share the first common subpixel CP, and characteristics of the first through third pixel groups PG1 through PG3 are as described above with reference to FIGS. 7 and 8.

For example, the first pixel group PG1 may include the first common subpixel CP, and the first common subpixel CP may be the first auxiliary subpixel PX1. The first through third pixel groups PG1 through PG3 may share the first common subpixel CP, and characteristics of the first through third pixel groups PG1 through PG3 are as described above with reference to FIGS. 7 through 9.

The shape of the second auxiliary subpixel PX2 may be polygonal in a plan view. For example, the shape of the second auxiliary subpixel PX2 may be quadrangular (or rectangular) in a plan view. When the shape of the second auxiliary subpixel PX2 is quadrangular (or rectangular), the corners of the quadrangle (or rectangle) may be sharpened or rounded. For example, when the shape of the second auxiliary subpixel PX2 is rectangular, the second auxiliary subpixel PX2 may be arranged between the first auxiliary subpixel PX1 and the third auxiliary subpixel PX3, a longer side of the second auxiliary subpixel PX2 may be arranged to be parallel to one side of the first auxiliary subpixel PX1 or the third auxiliary subpixel PX3, and a shorter side of the second auxiliary subpixel PX2 may be arranged near a transmission portion arranged inside a virtual polygon. For example, a lengthwise direction of the second auxiliary subpixel PX2 may be oriented toward the transmission portion arranged inside a virtual polygon most adjacent to the second auxiliary subpixel PX2.

The shape of the third auxiliary subpixel PX3 may be polygonal in a plan view. For example, the shape of the third auxiliary subpixel PX3 may be an irregular hexagon in a plan view. When the shape of the third auxiliary subpixel PX3 is an irregular hexagon, the corners of the irregular hexagon may be sharpened or rounded.

In a plan view, the area of the first auxiliary subpixel PX1 may be greater than the area of the second auxiliary subpixel PX2, and may be the same as or similar to the area of the third auxiliary subpixel PX3. In this case, the first auxiliary subpixel PX1 may be a subpixel emitting a first wavelength band (e.g., a blue visible light range) that is least sensitive to the human eye or a third wavelength band (e.g., a red visible light range).

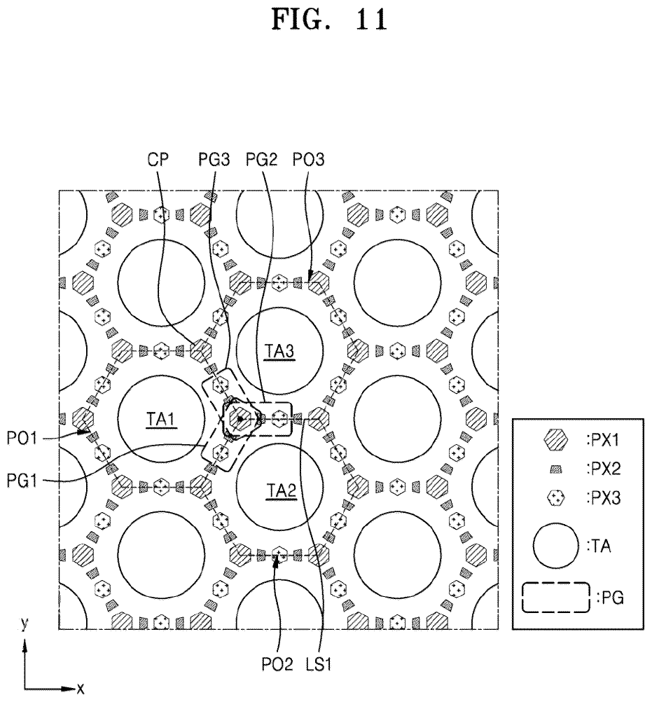

FIG. 11 is a plan view of the display panel 10, schematically showing an auxiliary subpixel pattern of the second display area DA2 of FIG. 1.

For reference, in the description of FIG. 11, the same description as that provided above with reference to FIGS. 1 through 10 may be omitted. A method in which pixel groups are driven and a correlation between the pixel groups and a common subpixel in FIG. 11 may be the same as the methods in which the pixel groups are driven and the correlations between the pixel groups and the common subpixel in FIGS. 7 through 10.

As shown in FIG. 11, the shape of the first auxiliary subpixel PX1 may be polygonal in a plan view. For example, the shape of the first auxiliary subpixel PX1 may be hexagonal in a plan view. When the shape of the first auxiliary subpixel PX1 is hexagonal, the corners of the hexagon may be sharpened or rounded. The shape of each of the first through third auxiliary subpixels PX1 through PX3 of FIG. 11 may have characteristics of the shape of each of the first through third auxiliary subpixels PX1 through PX3 of FIG. 8.

A first virtual polygon PO1 may be adjacent to a second virtual polygon PO2. For example, the first virtual polygon PO1 and the second virtual polygon PO2 may share one virtual line segment. A first pixel group PG1 may be disposed on the one virtual line segment shared by the first virtual polygon PO1 and the second virtual polygon PO2, and the first pixel group PG1 may include at least three auxiliary subpixels. For example, the virtual line segment shared by the first virtual polygon PO1 and the second virtual polygon PO2, and the at least three auxiliary subpixels may be arranged to overlap each other. The three auxiliary subpixels may be arranged in the order of the first auxiliary subpixel PX1, the second auxiliary subpixel PX2, and the third auxiliary subpixel PX3.

The first virtual polygon PO1 may be adjacent to a third virtual polygon PO3. For example, the first virtual polygon PO1 and the third virtual polygon PO3 may share one virtual line segment. A second pixel group PG2 may be placed on the virtual line segment shared by the first virtual polygon PO1 and the third virtual polygon PO3, and the second pixel group PG2 may include at least three auxiliary subpixels (e.g., the arrangement order thereof may be the same as that of the at least three auxiliary subpixels of the first pixel group PG1).

A third virtual polygon PO3 may be adjacent to the second virtual polygon PO2. For example, the third virtual polygon PO3 and the second virtual polygon PO2 may share one virtual line segment. A third pixel group PG3 may be placed on the virtual line segment shared by the third virtual polygon PO3 and the second virtual polygon PO2, and the third pixel group PG3 may include at least three auxiliary subpixels (e.g., the arrangement order thereof may be the same as that of the at least three auxiliary subpixels of the first pixel group PG1).

The first through third pixel groups PG1 through PG3 may share the first common subpixel CP, and the first common subpixel CP may be the first auxiliary subpixel PX1. For example, the first common subpixel CP may be disposed to overlap an intersection shared by the first virtual line segment LS1, the second virtual line segment LS2, and the third virtual line segment LS3.

For example, the first through third pixel groups PG1 through PG3 may be arranged to extend radially from the first common subpixel CP, the first pixel group PG1 and the second pixel group PG2 may be arranged to overlap the first virtual polygon PO1, and the third pixel group PG3 may be arranged to overlap the second virtual polygon PO2 adjacent to the first virtual polygon PO1.

There may be at least five auxiliary subpixels overlapping the first virtual line segment LS1. For example, a pixel group overlapping the first virtual line segment LS1 may be two pixel groups including the first pixel group PG1, and the two pixel groups overlapping the first virtual line segment LS1 may share, as a common subpixel, the third auxiliary subpixel PX3 located at the center of the first virtual line segment LS1.

There may be at least five auxiliary subpixels overlapping the second virtual line segment LS2. For example, a pixel group overlapping the second virtual line segment LS2 may be two pixel groups including the second pixel group PG2, and the two pixel groups overlapping the second virtual line segment LS2 may share, as a common subpixel, the third auxiliary subpixel PX3 located at the center of the second virtual line segment LS2.

There may be at least five auxiliary subpixels overlapping the third virtual line segment LS3. For example, a pixel group overlapping the third virtual line segment LS3 may be two pixel groups including the third pixel group PG3, and the two pixel groups overlapping the third virtual line segment LS3 may share, as a common subpixel, the third auxiliary subpixel PX3 located at the center of the third virtual line segment LS3.

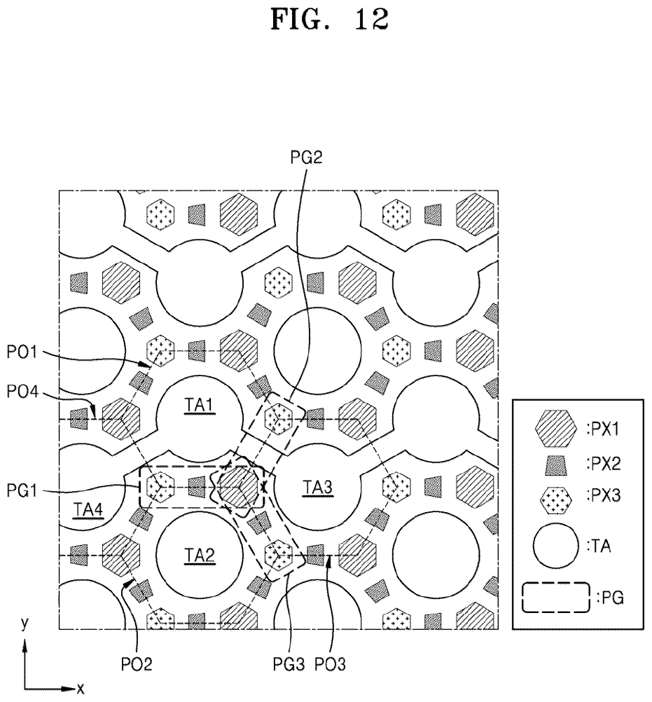

FIG. 12 is a plan view of the display panel 10, schematically showing an auxiliary subpixel pattern of the second display area DA2 of FIG. 1.

For reference, in the description of FIG. 12, the same description as that provided above with reference to FIGS. 1 through 11 may be omitted. A method in which pixel groups are driven and a correlation between the pixel groups and a common subpixel in FIG. 12 may be the same as the methods in which the pixel groups are driven and the correlations between the pixel groups and the common subpixel in FIGS. 7 through 11.

As illustrated in FIG. 12, a first transmission portion TA1 may be arranged inside a first virtual polygon PO1 in a plan view, a second transmission portion TA2 may be arranged inside a second virtual polygon PO2 in a plan view, a third transmission portion TA3 may be arranged inside a third virtual polygon PO3 in a plan view, and a fourth transmission portion TA4 may be arranged inside a fourth virtual polygon PO4 in a plan view.

For example, the first virtual polygon PO1 may be adjacent to the second virtual polygon PO2, the third virtual polygon PO3, and the fourth virtual polygon PO4. Assuming that there is a virtual axis that passes through the first virtual polygon PO1 and is parallel to a y axis, the third virtual polygon PO3 and the fourth virtual polygon PO4 may be arranged symmetrically with respect to the virtual axis.

The first transmission portion TA1 and the third transmission portion TA3 may be one transmission portion. For example, the first auxiliary subpixel PX1 and the third auxiliary subpixel PX3 may be arranged to overlap a single virtual line segment shared by the first virtual polygon PO1 and the third virtual polygon PO3, and the second auxiliary subpixel PX2 may be omitted. The first transmission portion TA1 and the second transmission portion TA2 may be connected to each other through an area where the second auxiliary subpixel PX2 is omitted. The first transmission portion TA1 and the second transmission portion TA2 may extend to an area where the second auxiliary subpixel PX2 is omitted, and may be connected to each other to form one transmission portion.

The first transmission portion TA1 and the fourth transmission portion TA4 may be one transmission portion. For example, the first auxiliary subpixel PX1 and the third auxiliary subpixel PX3 may be arranged to overlap a single virtual line segment shared by the first virtual polygon PO1 and the fourth virtual polygon PO4, and the second auxiliary subpixel PX2 may be omitted. The first transmission portion TA1 and the fourth transmission portion TA4 may be connected to each other through the area where the second auxiliary subpixel PX2 is omitted. The first transmission portion TA1 and the fourth transmission portion TA4 may extend to the area where the second auxiliary subpixel PX2 is omitted, and may be connected to each other to form one transmission portion.

For example, the first transmission portion TA1, the third transmission portion TA3, and the fourth transmission portion TA4 may be connected to each other in an x-axis direction to form one transmission portion. Other transmission portions connected to the first transmission portion TA1, the third transmission portion TA3, and the fourth transmission portion TA4 in the x-axis direction may be further arranged. However, another transmission portion spaced apart from the first transmission portion TA1 in a y-axis direction may not be connected to the first transmission portion TA1, and may be connected to the first transmission portion TA1 and thus may not form a single transmission portion.

For example, the first through third pixel groups PG1 through PG3 may be arranged to extend radially from the first common subpixel CP, the first pixel group PG1 and the second pixel group PG2 may be arranged to overlap the first virtual polygon PO1, and the third pixel group PG3 may be arranged to overlap the second virtual polygon PO2 adjacent to the first virtual polygon PO1.

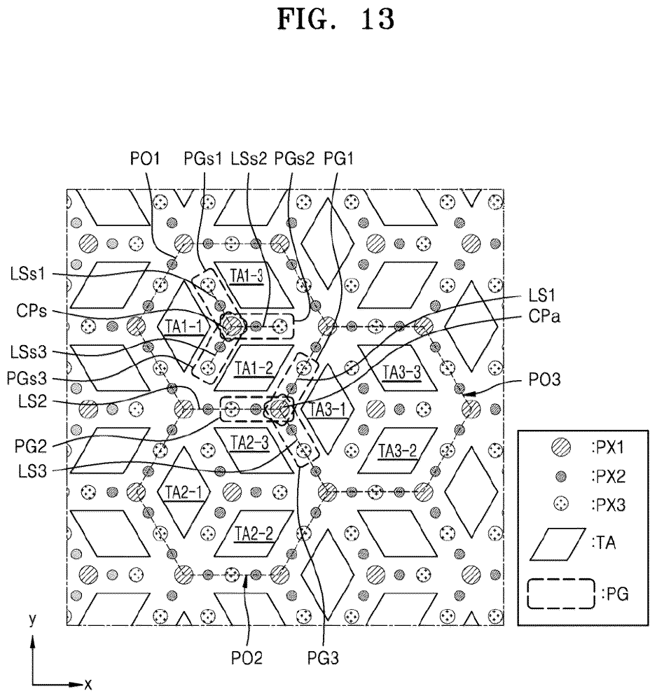

FIG. 13 is a plan view of the display panel 10, schematically showing an auxiliary subpixel pattern of the second display area DA2 of FIG. 1.

For reference, in the description of FIG. 13, the same description as that provided above with reference to FIGS. 1 through 12 may be omitted. A method in which pixel groups are driven and a correlation between the pixel groups and a common subpixel in FIG. 13 may be the same as the methods in which the pixel groups are driven and the correlations between the pixel groups and the common subpixel in FIGS. 7 through 12.

As illustrated in FIG. 13, at least one transmission portion and at least one auxiliary pixel group may be disposed within a virtual polygon in a plan view. For example, respective shapes of virtual polygons may be hexagonal in a plan view.

A first virtual polygon PO1 may be adjacent to a second virtual polygon PO2. For example, the first virtual polygon PO1 and the second virtual polygon PO2 may share one virtual line segment. A first pixel group PG1 may be disposed on the one virtual line segment shared by the first virtual polygon PO1 and the second virtual polygon PO2, and the first pixel group PG1 may include at least three auxiliary subpixels. For example, a first virtual line segment LS1 shared by the first virtual polygon PO1 and the second virtual polygon PO2, and the at least three auxiliary subpixels may be arranged to overlap each other. The at least three auxiliary subpixels may be arranged in the order of a first auxiliary subpixel PX1, a second auxiliary subpixel PX2, and a third auxiliary subpixel PX3.

For example, the first through third pixel groups PG1 through PG3 may be arranged to extend radially from the first common subpixel CP, the first pixel group PG1 and the second pixel group PG2 may be arranged to overlap the first virtual polygon PO1, and the third pixel group PG3 may be arranged to overlap the second virtual polygon PO2 adjacent to the first virtual polygon PO1.

A first auxiliary pixel group PGs1, a second auxiliary pixel group PGs2, and a third auxiliary pixel group PGs3 may be arranged inside the first virtual polygon PO1. The first auxiliary pixel group PGs1 may include a first auxiliary common subpixel CPs, and the first auxiliary common subpixel CPs may be arranged to overlap the center of the first virtual polygon PO1 in a plan view. The first auxiliary common subpixel CPs may be the first auxiliary subpixel PX1.

For example, first, second, and third auxiliary virtual line segments LSs1, LSs2, and LSs3 extending radially from the center of the first virtual polygon PO1 may be arranged within the first virtual polygon PO1. The second auxiliary virtual line segment LSs2 may have an angle of about 120 degrees with respect to the first auxiliary virtual line segment LSs1, and the third auxiliary virtual line segment LSs3 may have an angle of about 120 degrees with respect to the second auxiliary virtual line segment LSs2.

The first auxiliary pixel group PGs1 may be arranged to overlap the first auxiliary virtual line segment LSs1 in a plan view, the second auxiliary pixel group PGs2 may be arranged to overlap the second auxiliary virtual line segment LSs2 in a plan view, and the third auxiliary pixel group PGs3 may be arranged to overlap the third auxiliary virtual line segment LSs3 in a plan view.

For example, the first auxiliary pixel group PGs1 may include at least three auxiliary subpixels. For example, the first auxiliary virtual line segment LSs1 and the at least three auxiliary subpixels may be arranged to overlap each other in a plan view. The three auxiliary subpixels may be arranged in the order of the first auxiliary subpixel PX1, the second auxiliary subpixel PX2, and the third auxiliary subpixel PX3.

For example, the first through third auxiliary pixel groups PGs1 through PGs3 may be arranged to extend radially from the first auxiliary common subpixel CPs, and the first through third auxiliary pixel groups PGs1 through PGs3 may be arranged within the first virtual polygon PO1.

For example, when the first auxiliary pixel group PGs1 is turned on, the first auxiliary common subpixel CPs may emit light, based on a fourth control command for controlling the first auxiliary pixel group PGs1. For example, when the first auxiliary pixel group PGs1 and the second auxiliary pixel group PGs2 are turned on, the first auxiliary common subpixel CPs may emit light, based on the fourth control command for controlling the first auxiliary pixel group PGs1 and a fifth control command for controlling the second auxiliary pixel group PGs2. For example, when the first through third auxiliary pixel groups PGs1 through PGs3 are turned on, the first auxiliary common subpixel CPs may emit light, based on the fourth control command for controlling the first auxiliary pixel group PGs1, the fifth control command for controlling the second auxiliary pixel group PGs2, and a sixth control command for controlling the third auxiliary pixel group PGs3.

For example, when one auxiliary pixel group among the first through third auxiliary pixel groups PGs1 through PGs3 is turned on, the first auxiliary common subpixel CPs may emit light with a fourth brightness. Alternatively, when one auxiliary pixel group among the first through third auxiliary pixel groups PGs1 through PGs3 is turned on, a driving current with a first magnitude may flow in the first auxiliary common subpixel CPs.

For example, when two auxiliary pixel groups among the first through third auxiliary pixel groups PGs1 through PGs3 are turned on, the first auxiliary common subpixel CPs may emit light with a fifth brightness greater than the fourth brightness. Alternatively, when one auxiliary pixel group among the first through third auxiliary pixel groups PGs1 through PGs3 is turned on, a driving current with a fifth magnitude greater than the fourth magnitude may flow in the first auxiliary common subpixel CPs. For example, the fifth magnitude may be twice the fourth magnitude.

For example, when three auxiliary pixel groups among the first through third auxiliary pixel groups PGs1 through PGs3 are turned on, the first auxiliary common subpixel CPs may emit light with a sixth brightness greater than the fifth brightness. Alternatively, when three auxiliary pixel groups among the first through third auxiliary pixel groups PGs1 through PGs3 are turned on, a driving current with a sixth magnitude greater than the fifth magnitude may flow in the first auxiliary common subpixel CPs. For example, the sixth magnitude may be triple the fourth magnitude.

At least one transmission portion may be disposed within each of a plurality of virtual polygons. For example, a 1-1 auxiliary transmission portion TA1-1, a 1-2 auxiliary transmission portion TA1-2, and a 1-3 auxiliary transmission portion TA1-3 may be arranged inside the first virtual polygon PO1. The 1-1 auxiliary transmission portion TA1-1 may be disposed between the first auxiliary virtual line segment LSs1 and the third auxiliary virtual line segment LSs3 within the first virtual polygon PO1. For example, the 1-1 auxiliary transmission portion TA1-1 may be disposed around an interior angle formed by the first auxiliary virtual line segment LSs1 and the third auxiliary virtual line segment LSs3 within the first virtual polygon PO1.

For example, the 1-2 auxiliary transmission portion TA1-2 may be disposed between the second auxiliary virtual line segment LSs2 and the third auxiliary virtual line segment LSs3 within the first virtual polygon PO1. For example, the 1-2 auxiliary transmission portion TA1-2 may be disposed around an interior angle formed by the second auxiliary virtual line segment LSs2 and the third auxiliary virtual line segment LSs3 within the first virtual polygon PO1.

For example, the 1-3 auxiliary transmission portion TA1-3 may be disposed between the first auxiliary virtual line segment LSs1 and the second auxiliary virtual line segment LSs2 within the first virtual polygon PO1. For example, the 1-3 auxiliary transmission portion TA1-3 may be disposed around an interior angle formed by the first auxiliary virtual line segment LSs1 and the second auxiliary virtual line segment LSs2 within the first virtual polygon PO1.

For example, the shape of each of the 1-1 through 1-3 auxiliary transmission portions TA1-1 through TA1-3 may be a rhombus in a plan view. Alternatively, unlike FIG. 13, the 1-1 through 1-3 auxiliary transmission portions TA1-1 through TA1-3 may all be connected to each other to form one transmission portion. In this case, the 1-1 through 1-3 auxiliary transmission portions TA1-1 through TA1-3 may be arranged to surround the first through third auxiliary pixel groups PGs1 through PGs3 in a plan view.

For example, 2-1, 2-2, and 2-3 auxiliary transmission portions TA2-1, TA2-2, and TA2-3 may be arranged inside the second virtual polygon PO2, and 3-1, 3-2, and 3-3 auxiliary transmission portions TA3-1, TA3-2, and TA3-3 may be arranged inside the third virtual polygon PO3. At least one auxiliary transmission portion may also be disposed within each of other virtual polygons.

For example, the shape of each of the 2-1 through 2-3 auxiliary transmission portions TA2-1 through TA2-3 and the 3-1 through 3-3 auxiliary transmission portions TA3-1 through TA3-3 may be a rhombus in a plan view. Alternatively, unlike FIG. 13, the 2-1 through 2-3 auxiliary transmission portions TA2-1 through TA2-3 may all be connected to each other to form one transmission portion. In this case, the 2-1 through 2-3 auxiliary transmission portions TA2-1 through TA2-3 may be arranged to surround auxiliary pixel groups arranged in the second virtual polygon PO2. Alternatively, unlike FIG. 13, the 3-1 through 3-3 auxiliary transmission portions TA3-1 through TA3-3 may all be connected to each other to form one transmission portion. In this case, the 3-1 through 3-3 auxiliary transmission portions TA3-1 through TA3-3 may be arranged to surround auxiliary pixel groups arranged in the third virtual polygon PO3.

There may be at least five auxiliary subpixels overlapping the first virtual line segment LS1. For example, a pixel group overlapping the first virtual line segment LS1 may be two pixel groups including the first pixel group PG1, and the two pixel groups overlapping the first virtual line segment LS1 may share, as a common subpixel, the third auxiliary subpixel PX3 located at the center of the first virtual line segment LS1.

There may be at least five auxiliary subpixels overlapping the second virtual line segment LS2. For example, a pixel group overlapping the second virtual line segment LS2 may be two pixel groups including the second pixel group PG2, and the two pixel groups overlapping the second virtual line segment LS2 may share, as a common subpixel, the third auxiliary subpixel PX3 located at the center of the second virtual line segment LS2.

There may be at least five auxiliary subpixels overlapping the third virtual line segment LS3. For example, a pixel group overlapping the third virtual line segment LS3 may be two pixel groups including the third pixel group PG3, and the two pixel groups overlapping the third virtual line segment LS3 may share, as a common subpixel, the third auxiliary subpixel PX3 located at the center of the third virtual line segment LS3.

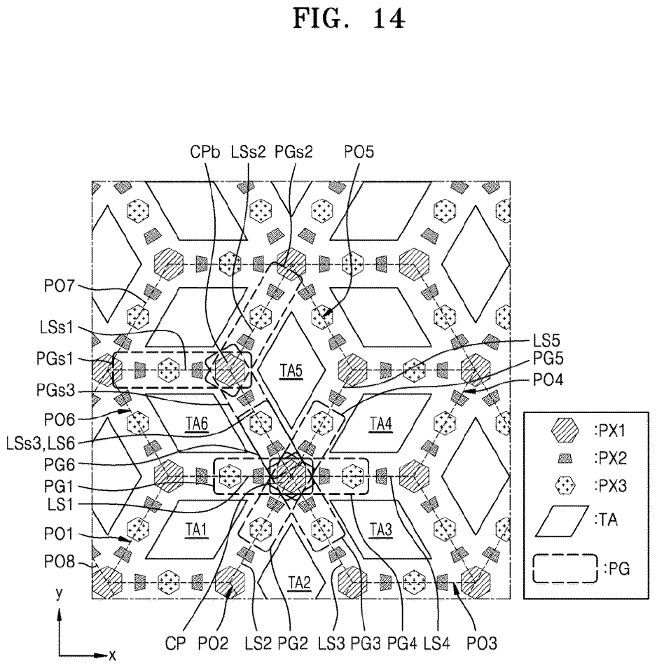

FIG. 14 is a plan view of the display panel 10, schematically showing an auxiliary subpixel pattern of the second display area DA2 of FIG. 1.

For reference, in the description of FIG. 14, the same description as that provided above with reference to FIGS. 1 through 13 may be omitted. A method in which pixel groups are driven and a correlation between the pixel groups and a common subpixel in FIG. 14 may be the same as the methods in which the pixel groups are driven and the correlations between the pixel groups and the common subpixel in FIGS. 7 through 13.

As shown in FIG. 14, each of a plurality of virtual polygons may have a shape of a rhombus in a plan view. For example, six virtual polygons may be arranged in a plan view to contact each other at a first intersection. The first common subpixel CP may be disposed so as to overlap, in a plan view, the first intersection where the six virtual polygons meet.

A first virtual polygon PO1 may be adjacent to a second virtual polygon PO2. For example, the first virtual polygon PO1 and the second virtual polygon PO2 may share one virtual line segment. A first pixel group PG1 may be disposed on the one virtual line segment shared by the first virtual polygon PO1 and the second virtual polygon PO2, and the first pixel group PG1 may include at least three auxiliary subpixels.

For example, the virtual line segment shared by the first virtual polygon PO1 and the second virtual polygon PO2, and the at least three auxiliary subpixels may be arranged to overlap each other. The at least three auxiliary subpixels may be arranged in the order of a first auxiliary subpixel PX1, a second auxiliary subpixel PX2, and a third auxiliary subpixel PX3. The first pixel group PG1 may include the first common subpixel CP, and the first common subpixel CP may be one of the at least three auxiliary subpixels, and may be the first auxiliary subpixel PX1.

For example, first, second, third, fourth, fifth, and sixth pixel groups PG1, PG2, PG3, PG4, PG5, and PG6 may be arranged to extend radially from the first common subpixel CP. The first pixel group PG1 may be arranged to overlap a first virtual line segment LS1, the second pixel group PG2 may be arranged to overlap a second virtual line segment LS2, the third pixel group PG3 may be arranged to overlap a third virtual line segment LS3, the fourth pixel group PG4 may be arranged to overlap a fourth virtual line segment LS4, the fifth pixel group PG5 may be arranged to overlap a fifth virtual line segment LS5, and the sixth pixel group PG6 may be arranged to overlap a sixth virtual line segment LS6.

The first through sixth virtual line segments LS1 through LS6 may share one intersection, and may extend radially from the intersection. The first virtual line segment LS1 and the second virtual line segment LS2 may be portions of the first virtual polygon PO1, the second virtual line segment LS2 and the third virtual line segment LS3 may be portions of the second virtual polygon PO2, the third virtual line segment LS3 and the fourth virtual line segment LS4 may be portions of the third virtual polygon PO3, the fourth virtual line segment LS4 and the fifth virtual line segment LS5 may be portions of the fourth virtual polygon PO4, the fifth virtual line segment LS5 and the sixth virtual line segment LS6 may be portions of the fifth virtual polygon PO5, and the sixth virtual line segment LS6 and the first virtual line segment LS1 may be portions of the sixth virtual polygon PO6.

The first through sixth pixel groups PG1 through PG6 may include the first common subpixel CP. The first through sixth pixel groups PG1 through PG6 may share the first common subpixel CP.

For example, when one pixel group among the first through sixth pixel groups PG1 through PG6 is turned on, the first common subpixel CP may emit light with a first brightness. Alternatively, when one pixel group among the first through sixth pixel groups PG1 through PG6 is turned on, a driving current with a first magnitude may flow in the first common subpixel CP.

For example, when two pixel groups among the first through sixth pixel groups PG1 through PG6 are turned on, the first common subpixel CP may emit light with a second brightness that is greater than the first brightness. Alternatively, when two pixel groups among the first through sixth pixel groups PG1 through PG6 are turned on, a driving current with a second magnitude greater than the first magnitude may flow in the first common subpixel CP. For example, the second magnitude may be twice the first magnitude.

For example, when three pixel groups among the first through sixth pixel groups PG1 through PG6 are turned on, the first common subpixel CP may emit light with a third brightness that is greater than the second brightness. Alternatively, when three pixel groups among the first through sixth pixel groups PG1 through PG6 are turned on, a driving current with a third magnitude greater than the second magnitude may flow in the first common subpixel CP. For example, the third magnitude may be triple the first magnitude.

As such, the first common subpixel CP may have a brightness that is proportional to the number of pixel groups turned on among the first through sixth pixel groups PG1 through PG6. Alternatively, the driving current flowing in the first common subpixel CP may have a magnitude that is proportional to the number of pixel groups turned on among the first through sixth pixel groups PG1 through PG6.

In a plan view, a transmission portion may be disposed within each of a plurality of virtual polygons. For example, in a plan view, a first transmission portion TA1 may be arranged within the first virtual polygon PO1, a second transmission portion TA2 may be arranged within the second virtual polygon PO2, a third transmission portion TA3 may be arranged within the third virtual polygon PO3, a fourth transmission portion TA4 may be arranged within the fourth virtual polygon PO4, a fifth transmission portion TA5 may be arranged within the fifth virtual polygon PO5, and a sixth transmission portion TA6 may be arranged within the sixth virtual polygon PO6. A transmission portion may also be disposed within each of seventh and eighth virtual polygons PO7 and PO8. For example, respective planar shapes of a plurality of transmission portions may be identical to or similar to the shape of a virtual polygon. Accordingly, respective shapes of the plurality of virtual polygons may be rhombi, and the shape of the transmission portion arranged inside each of the plurality of virtual polygons may also be a rhombus.

As illustrated in FIG. 14, the sixth virtual polygon PO6, the fifth virtual polygon PO5, and the seventh virtual polygon PO7 may be arranged in a plan view so as to contact each other at a second intersection. For example, the sixth virtual polygon PO6 and the fifth virtual polygon PO5 may share one virtual line segment. One end of one virtual line segment shared by the sixth virtual polygon PO6 and the fifth virtual polygon PO5 may be the first intersection, and the other end thereof may be the second intersection. A sixth pixel group PG6 may be disposed on the one virtual line segment shared by the first auxiliary pixel group PGs1 and the fifth virtual polygon PO5, and the first auxiliary pixel group PGs1 may include at least five auxiliary subpixels.

The first auxiliary pixel group PGs1 may include a second common subpixel CPb. The first through third pixel groups PGs1 through PGs3 may include the second common subpixel CPb. The first through third pixel groups PGs1 through PGs3 may share the second common subpixel CPb.

First, second, and third auxiliary pixel groups PGs1, PGs2, and PGs3 may include the second common subpixel CPb. The first through third auxiliary pixel groups PGs1 through PGs3 may share the second common subpixel CPb.

For example, the first through third auxiliary pixel groups PGs1 through PGs3 may be arranged to extend radially from the second common subpixel CPb. The first auxiliary pixel group PGs1 may be arranged to overlap a first auxiliary virtual line segment LSs1, the second auxiliary pixel group PGs2 may be arranged to overlap a second auxiliary virtual line segment LSs2, and the third auxiliary pixel group PGs3 may be arranged to overlap a third auxiliary virtual line segment LSs3. The first through third auxiliary virtual line segments LSs1 through LSs3 may share one intersection.

For example, when one auxiliary pixel group among the first through third auxiliary pixel groups PGs1 through PGs3 is turned on, the second auxiliary common subpixel CPb may emit light with a fourth brightness. Alternatively, when one auxiliary pixel group among the first through third auxiliary pixel groups PGs1 through PGs3 is turned on, a driving current with a fifth magnitude greater than the fourth magnitude may flow in the second auxiliary common subpixel CPb.

For example, when two auxiliary pixel groups among the first through third auxiliary pixel groups PGs1 through PGs3 are turned on, the second auxiliary common subpixel CPb may emit light with a fifth brightness greater than the fourth brightness. Alternatively, when two auxiliary pixel groups among the first through third auxiliary pixel groups PGs1 through PGs3 are turned on, a driving current with a fifth magnitude greater than the fourth magnitude may flow in the second auxiliary common subpixel CPb. For example, the fifth magnitude may be twice the fourth magnitude.

For example, when three auxiliary pixel groups among the first through third auxiliary pixel groups PGs1 through PGs3 are turned on, the second auxiliary common subpixel CPb may emit light with a sixth brightness greater than the fifth brightness. Alternatively, when three auxiliary pixel groups among the first through third auxiliary pixel groups PGs1 through PGs3 are turned on, a driving current with a sixth magnitude greater than the fifth magnitude may flow in the second auxiliary common subpixel CPb. For example, the sixth magnitude may be triple the fourth magnitude.

For example, vertices located at both ends of one virtual line segment shared by two virtual polygons may be defined, one of the vertices may be shared by a total of N1 pixel groups, and the other of the vertices may be shared by N2 pixel groups, where N1 and N2 are natural numbers, and N1 may be greater than N2. In the example of FIG. 14, a first vertex may be shared by a total of six pixel groups, and a second vertex may be shared by a total of three pixel groups.

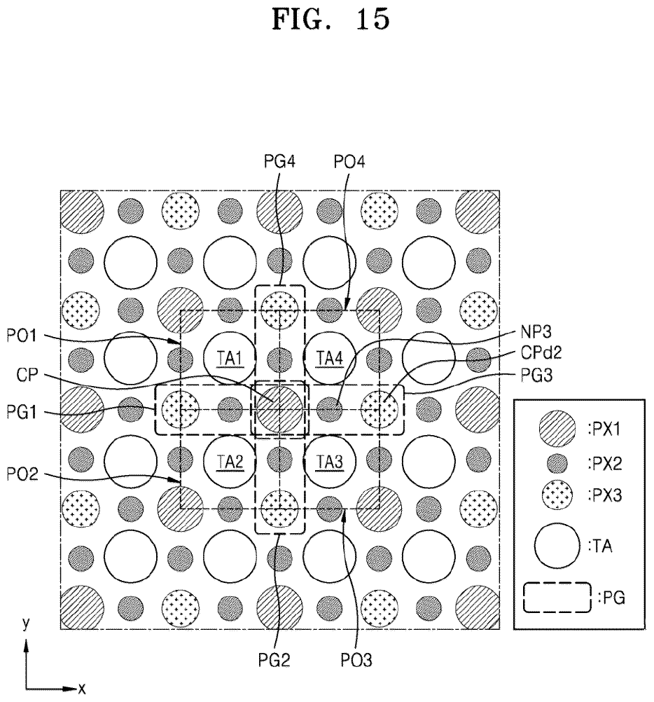

FIG. 15 is a plan view of the display panel 10, schematically showing an auxiliary subpixel pattern of the second display area DA2 of FIG. 1.

For reference, in the description of FIG. 15, the same description as that provided above with reference to FIGS. 1 through 14 may be omitted. A method in which pixel groups are driven and a correlation between the pixel groups and a common subpixel in FIG. 15 may be the same as the methods in which the pixel groups are driven and the correlations between the pixel groups and the common subpixel in FIGS. 7 through 14.

As shown in FIG. 15, each of a plurality of virtual polygons may have a shape of a quadrangle in a plan view. A first virtual polygon PO1 may be adjacent to a second virtual polygon PO2. For example, the first virtual polygon PO1 and the second virtual polygon PO2 may share one virtual line segment.

A first pixel group PG1 may be disposed on the one virtual line segment shared by the first virtual polygon PO1 and the second virtual polygon PO2, and the first pixel group PG1 may include at least three auxiliary subpixels. For example, the virtual line segment shared by the first virtual polygon PO1 and the second virtual polygon PO2, and the at least three auxiliary subpixels may be arranged to overlap each other. The at least three auxiliary subpixels may be arranged in the order of the first auxiliary subpixel PX1, the second auxiliary subpixel PX2, and the third auxiliary subpixel PX3.

The second pixel group PG2 may be disposed to overlap one virtual line segment shared by the second virtual polygon PO2 and the third virtual polygon PO3. The third pixel group PG3 may be disposed to overlap one virtual line segment shared by the third virtual polygon PO3 and the fourth virtual polygon PO4. The fourth pixel group PG4 may be disposed to overlap one virtual line segment shared by the fourth virtual polygon PO4 and the first virtual polygon PO1.

The second through fourth pixel groups PG2 through PG4 may include at least three auxiliary subpixels. The at least three auxiliary subpixels may be arranged in the order of the first auxiliary subpixel PX1, the second auxiliary subpixel PX2, and the third auxiliary subpixel PX3.

For example, the first through fourth pixel groups PG1 through PG4 may commonly include the first common subpixel CP. The first through fourth pixel groups PG1 through PG4 may share the first common subpixel CP. The first common subpixel CP shared by the first through fourth pixel groups PG1 through PG4 may be the first auxiliary subpixel PX1.

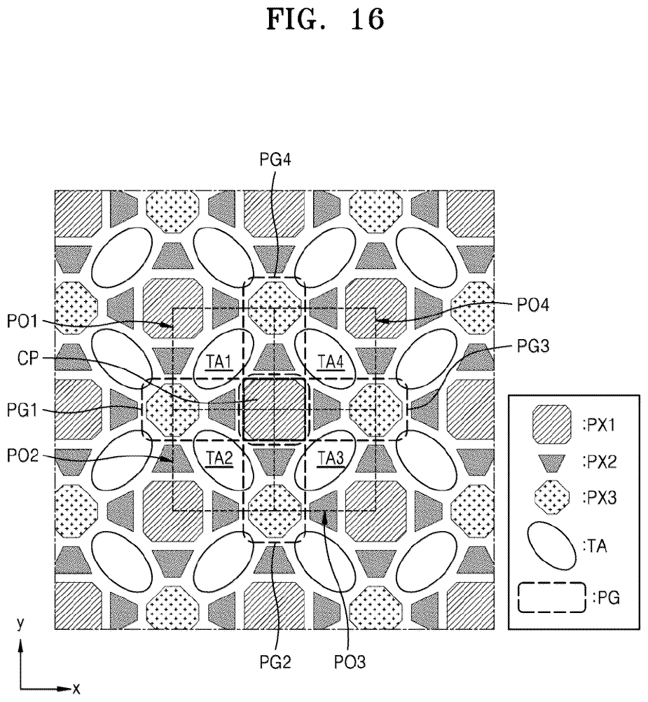

FIG. 16 is a plan view of the display panel 10, schematically showing an auxiliary subpixel pattern of the second display area DA2 of FIG. 1.

For reference, in the description of FIG. 16, the same description as that provided above with reference to FIGS. 1 through 15 may be omitted. A method in which pixel groups are driven and a correlation between the pixel groups and a common subpixel in FIG. 16 may be the same as the methods in which the pixel groups are driven and the correlations between the pixel groups and the common subpixel in FIGS. 7 through 15.

As illustrated in FIG. 16, a shape of a first transmission portion TA1 disposed within a first virtual polygon PO1 may be elliptical. A shape of a second transmission portion TA2 disposed within a second virtual polygon PO2 may be elliptical. A shape of a third transmission portion TA3 disposed within a third virtual polygon PO3 may be elliptical. A shape of a fourth transmission portion TA4 disposed within a fourth virtual polygon PO4 may be elliptical.

For example, when the shape of the first transmission portion TA1 is elliptical, one end of a longer axis of the first transmission portion TA1 may be directed toward a third auxiliary subpixel PX3 of a first pixel group PG1, and another end of the longer axis of the first transmission portion TA1 may be directed toward a third auxiliary subpixel PX3 of a fourth pixel group PG4.

For example, when the shape of the second transmission portion TA2 is elliptical, one end of a longer axis of the second transmission portion TA2 may be directed toward the third auxiliary subpixel PX3 of the first pixel group PG1, and another end of the longer axis of the second transmission portion TA2 may be directed toward a third auxiliary subpixel PX3 of a second pixel group PG2.

For example, when the shape of the third transmission portion TA3 is elliptical, one end of a longer axis of the third transmission portion TA3 may be directed toward the third auxiliary subpixel PX3 of the second pixel group PG2, and another end of the longer axis of the third transmission portion TA3 may be directed toward a third auxiliary subpixel PX3 of a third pixel group PG3.

For example, when the shape of the fourth transmission portion TA4 is elliptical, one end of a longer axis of the fourth transmission portion TA4 may be directed toward the third auxiliary subpixel PX3 of the third pixel group PG3, and another end of the longer axis of the fourth transmission portion TA4 may be directed toward the third auxiliary subpixel PX3 of the fourth pixel group PG4.

The auxiliary subpixel pattern of FIG. 16 may be an example of a modification of the auxiliary subpixel pattern of FIG. 15. For example, a shape of the first auxiliary subpixel PX1 in a plan view may be a quadrangle or octagon with chamfered (or truncated) four corners. When the shape of the first auxiliary subpixel PX1 is a quadrangle or octagon with chamfered (or truncated) four corners, the corners of the quadrangle or octagon with four chamfered (or truncated) corners may be sharp or rounded.

For example, the shape of the second auxiliary subpixel PX2 may be trapezoidal in a plan view. When the shape of the second auxiliary subpixel PX2 is trapezoidal, the corners of the trapezoid may be sharp or rounded. For example, the shape of the second auxiliary subpixel PX2 may be a trapezoid having a bottom side having a relatively great length and an upper side having a less length than the bottom side. In this case, the bottom side may be placed near the first auxiliary subpixel PX1, and the upper side may be placed near the third auxiliary subpixel PX3. For example, the bottom side may be placed near an auxiliary subpixel having a larger area among the first auxiliary subpixel PX1 and the third auxiliary subpixel PX3. For example, the upper side may be placed near an auxiliary subpixel having a smaller area among the first auxiliary subpixel PX1 and the third auxiliary subpixel PX3.

For example, a shape of the third auxiliary subpixel PX3 in a plan view may be a quadrangle or octagon with chamfered (or truncated) four corners. For example, the planar area of the first auxiliary subpixel PX1 may be greater than the planar area of the third auxiliary subpixel PX3. When the shape of the third auxiliary subpixel PX3 is a quadrangle or octagon with chamfered (or truncated) four corners, the corners of the quadrangle or octagon with four chamfered (or truncated) corners may be sharp or rounded.

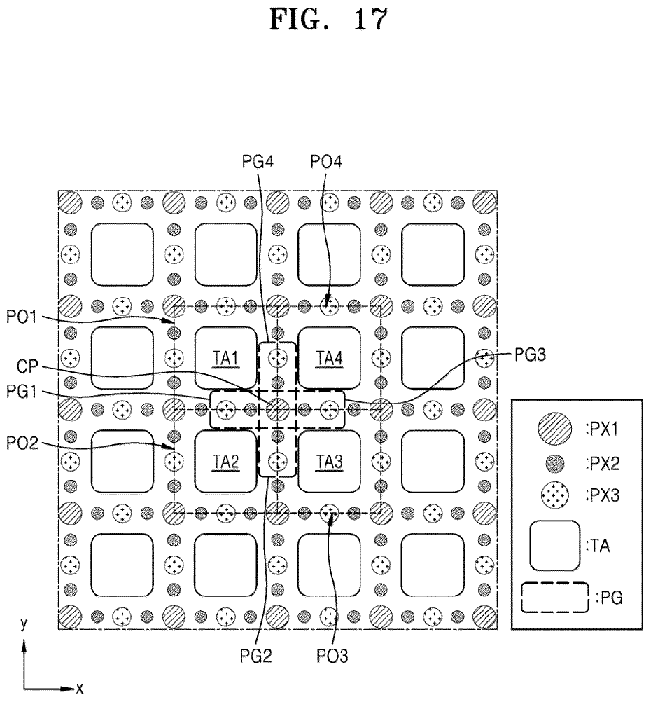

FIG. 17 is a plan view of the display panel 10, schematically showing an auxiliary subpixel pattern of the second display area DA2 of FIG. 1.

For reference, in the description of FIG. 17, the same description as that provided above with reference to FIGS. 1 through 16 may be omitted. A method in which pixel groups are driven and a correlation between the pixel groups and a common subpixel in FIG. 17 may be the same as the methods in which the pixel groups are driven and the correlations between the pixel groups and the common subpixel in FIGS. 7 through 16.

The auxiliary subpixel pattern of FIG. 17 may be an example of a modification of the auxiliary subpixel pattern of FIG. 16. For example, a shape of each auxiliary subpixel in a plan view may be transformed from a polygon (FIG. 16) to a circle (FIG. 17). The shape of each transmission portion in a plan view may be transformed from an ellipse to a rectangle with rounded corners.

A first pixel group PG1 may be disposed on one virtual line segment shared by a first virtual polygon PO1 and a second virtual polygon PO2. A second pixel group PG2 may be disposed on one virtual line segment shared by the second virtual polygon PO2 and a third virtual polygon PO3. A third pixel group PG3 may be disposed on one virtual line segment shared by the third virtual polygon PO3 and a fourth virtual polygon PO4. A fourth pixel group PG4 may be disposed on one virtual line segment shared by the fourth virtual polygon PO4 and the first virtual polygon PO1.

For example, each of the first through fourth pixel groups PG1 through PG4 may include at least five auxiliary subpixels, and the at least five auxiliary subpixels may be arranged in the order of a first auxiliary subpixel PX1, a second auxiliary subpixel PX2, a third auxiliary subpixel PX3, a second auxiliary subpixel PX2, and a first auxiliary subpixel PX1.

For example, the first through fourth pixel groups PG1 through PG4 may commonly include a first common subpixel CP. The first through fourth pixel groups PG1 through PG4 may share the first common subpixel CP. The first common subpixel CP shared by the first through fourth pixel groups PG1 through PG4 may be the first auxiliary subpixel PX1.

For example, a shape of each of the virtual polygons illustrated in FIG. 17 may be a square. For example, first auxiliary subpixels may be arranged at four corners of a virtual polygon (square). First auxiliary subpixels and second auxiliary subpixels may be alternately arranged between two third auxiliary subpixels. For example, respective shapes of the first through third auxiliary subpixels may be circular. As another example, the shape of the second auxiliary subpixel may be elliptical. Features of the virtual polygon of FIG. 17 may be also applied to other embodiments to be described later.

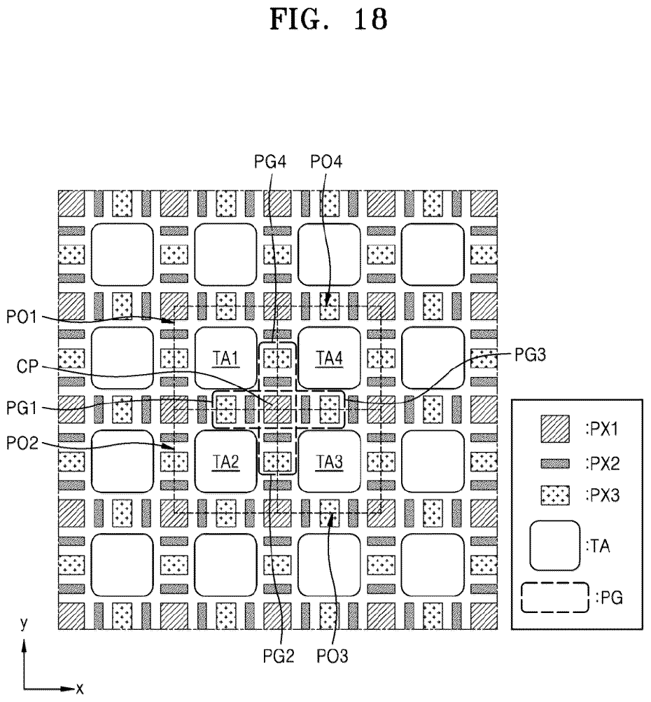

FIG. 18 is a plan view of the display panel 10, schematically showing an auxiliary subpixel pattern of the second display area DA2 of FIG. 1.

For reference, in the description of FIG. 18, the same description as that provided above with reference to FIGS. 1 through 17 may be omitted. A method in which pixel groups are driven and a correlation between the pixel groups and a common subpixel in FIG. 18 may be the same as the methods in which the pixel groups are driven and the correlations between the pixel groups and the common subpixel in FIGS. 7 through 17.

The auxiliary subpixel pattern of FIG. 18 may be an example of a modification of the auxiliary subpixel pattern of FIG. 17. For example, a shape of each auxiliary subpixel in a plan view may be transformed from a circle (FIG. 17) to a rectangle (FIG. 18).

For example, respective planar shapes of first, second, and third auxiliary subpixels PX1, PX2, and PX3 may be quadrangular, and a width of the first auxiliary subpixel PX1 may be largest and a width of the second auxiliary subpixel PX2 may be smallest. The shape of the second auxiliary subpixel PX2 may be rectangular, and a longer side of the second auxiliary subpixel PX2 may be arranged to face the first auxiliary subpixel PX1 and the third auxiliary subpixel PX3.

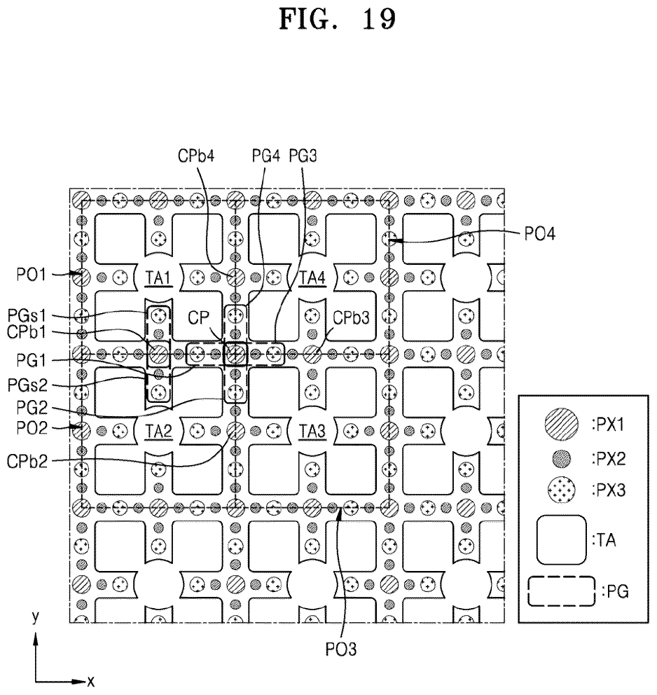

FIG. 19 is a plan view of the display panel 10, schematically showing an auxiliary subpixel pattern of the second display area DA2 of FIG. 1.

For reference, in the description of FIG. 19, the same description as that provided above with reference to FIGS. 1 through 18 may be omitted. A method in which pixel groups are driven and a correlation between the pixel groups and a common subpixel in FIG. 19 may be the same as the methods in which the pixel groups are driven and the correlations between the pixel groups and the common subpixel in FIGS. 7 through 18.

As shown in FIG. 19, each of a plurality of virtual polygons may have a shape of a quadrangle in a plan view. Virtual line segments forming the first virtual polygon PO1, and some of a plurality of auxiliary subpixels may be arranged to overlap each other in a plan view.

The others of the plurality of auxiliary subpixels may be arranged within the first virtual polygon PO1. For example, the others of the plurality of auxiliary subpixels may be arranged in a + shape within the first virtual polygon PO1. The others of the plurality of auxiliary subpixels may be arranged in a + shape within the first virtual polygon PO1, but may not be arranged in a central area of the inside of the first virtual polygon PO1.

For example, common subpixels may be arranged at virtual vertices or virtual edges constituting the first virtual polygon PO1. A pixel group may be formed to implement one dot around a common subpixel.

For example, a first common subpixel CP may be disposed to overlap one vertex of the first virtual polygon PO1. For example, the first common subpixel CP may be included in the first through fourth pixel groups PG1 through PG4. The first common subpixel CP may be shared by the first through fourth pixel groups PG1 through PG4.

For example, first, second, third, and fourth pixel groups PG1, PG2, PG3, and PG4 may be arranged to extend radially from the first common subpixel CP. The first pixel group PG1 may include at least three auxiliary subpixels. For example, the virtual line segments of the first virtual polygon PO1 and the at least three auxiliary subpixels may be arranged to overlap each other. The at least three auxiliary subpixels may be arranged in the order of a first auxiliary subpixel PX1 (first common subpixel CP), a second auxiliary subpixel PX2, and a third auxiliary subpixel PX3.

The virtual line segments forming the first virtual polygon PO1, and at least nine auxiliary subpixels may be arranged to overlap each other in a plan view. Auxiliary subpixels located at both ends among the at least nine auxiliary subpixels may be common subpixels shared by several pixel groups. An auxiliary subpixel located at the center among the at least nine auxiliary subpixels may be common subpixels shared by several pixel groups.

For example, when the at least nine auxiliary subpixels are arranged in an x-axis direction, auxiliary pixel groups that share the auxiliary subpixel located at the center of the at least nine auxiliary subpixels may be arranged in a y-axis direction. The auxiliary pixel groups may be arranged in a row toward a circular portion of a transmission portion that is to be described later.

Transmission portions may be arranged within the virtual polygons of FIG. 19. Planar shapes of the transmission portions may vary according to arrangements of pixel groups. A first transmission portion TA1 may be disposed inside the first virtual polygon PO1, a second transmission portion TA2 may be disposed inside a second virtual polygon PO2, a third transmission portion TA3 may be disposed inside a third virtual polygon PO3, and a fourth transmission portion TA4 may be disposed inside a fourth virtual polygon PO4.

For example, a shape of each of the first through fourth transmission portions TA1 through TA4 of FIG. 19 may be a shape obtained by combining a single circular shape with quadrangles arranged to surround the circular shape, one of the corners of each of the quadrangles may be connected to the circular shape, and respective borders of portions of the circular shape that are connected to the corners may be omitted.

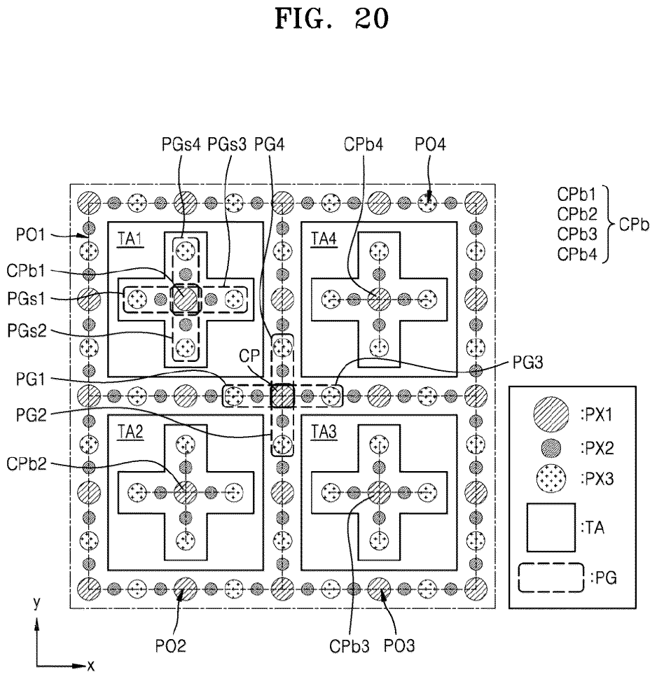

FIG. 20 is a plan view of the display panel 10, schematically showing an auxiliary subpixel pattern of the second display area DA2 of FIG. 1.

For reference, in the description of FIG. 20, the same description as that provided above with reference to FIGS. 1 through 19 may be omitted. A method in which pixel groups are driven and a correlation between the pixel groups and a common subpixel in FIG. 20 may be the same as the methods in which the pixel groups are driven and the correlations between the pixel groups and the common subpixel in FIGS. 7 through 19.

As illustrated in FIG. 20, first, second, third, and fourth pixel groups PG1, PG2, PG3, and PG4 may share a first common subpixel CPa, and first, second, third, and fourth auxiliary pixel groups PGs1, PGs2, PGs3, and PGs4 may share a second common subpixel CPb. In a plan view, the first through fourth auxiliary pixel groups PGs1 through PGs4 may be arranged inside the first virtual polygon PO1. In a plan view, the first through fourth auxiliary pixel groups PGs1 through PGs4 may be surrounded by pixel groups arranged to overlap the first virtual polygon PO1.

A first transmission portion TA1 may be disposed within the first virtual polygon PO1. In a plan view, the first through fourth auxiliary pixel groups PGs1 through PGs4 may be surrounded by the first transmission portion TA1. For example, the first transmission portion TA1 may be disposed between the first through fourth auxiliary pixel groups PGs1 through PGs4 and pixel groups arranged to overlap the first virtual polygon PO1.

For example, the second common subpixel CPb may include 2-1, 2-2, 2-3, and 2-4 common subpixels CPb1, CPb2, CPb3, and CPb4, the 2-1 common subpixel CPb1 may be disposed within the first virtual polygon PO1, the 2-2 common subpixel CPb2 may be disposed within a second virtual polygon PO2, the 2-3 common subpixel CPb3 may be disposed within a third virtual polygon PO3, and the 2-4 common subpixel CPb4 may be disposed within a fourth virtual polygon PO4. Each of the 2-1through 2-4 common subpixels CPb1 through CPb4 may be disposed at the center of a virtual polygon in a plan view.

The 2-1 common subpixel CPb1 shared by the first through fourth auxiliary pixel groups PGs1 through PGs4 may be disposed at the center of the first virtual polygon PO1. The 2-1 common subpixel may be a first auxiliary subpixel PX1, and each of the first through fourth auxiliary pixel groups PGs1 through PGs4 may include at least three auxiliary subpixels. The at least three auxiliary subpixels may be arranged in the order of a first auxiliary subpixel PX1 (second common subpixel CPb), a second auxiliary subpixel PX2, and a third auxiliary subpixel PX3.

The first through fourth auxiliary pixel groups PGs1 through PGs4 may be arranged in a + shape within the first virtual polygon PO1 centered on the 2-1 common subpixel. For example, the first auxiliary pixel group PGs1 and the second pixel group PGs3 may be arranged on one straight line, and the second auxiliary pixel groups PGs2 and the fourth pixel group PGs4 may be arranged on another straight line in a direction intersecting the one straight line.

For example, the second common subpixel CPb may include the 2-1, 2-2, 2-3, and 2-4 common subpixels CPb1, CPb2, CPb3, and CPb4, the 2-1 common subpixel CPb1 may be disposed within the first virtual polygon PO1, the 2-2 common subpixel CPb2 may be disposed within the second virtual polygon PO2, the 2-3common subpixel CPb3 may be disposed within the third virtual polygon PO3, and the 2-4 common subpixel CPb4 may be disposed within the fourth virtual polygon PO4. Each of the 2-1 through 2-4 common subpixels CPb1 through CPb4 may be disposed at the center of a virtual polygon in a plan view.

The first through fourth pixel groups PG1 through PG4 may include at least three auxiliary subpixels. The at least three auxiliary subpixels may be arranged in the order of a first auxiliary subpixel PX1 (first common subpixel CP), a second auxiliary subpixel PX2, and a third auxiliary subpixel PX3. There may be at least nine auxiliary subpixels overlapping virtual line segments constituting each virtual polygon.

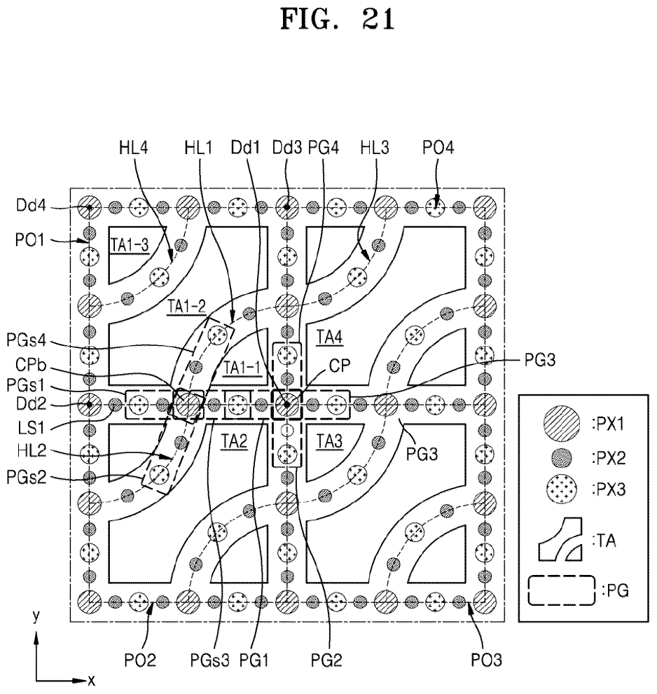

FIG. 21 is a plan view of the display panel 10, schematically showing an auxiliary subpixel pattern of the second display area DA2 of FIG. 1.

For reference, in the description of FIG. 21, the same description as that provided above with reference to FIGS. 1 through 20 may be omitted. A method in which pixel groups are driven and a correlation between the pixel groups and a common subpixel in FIG. 21 may be the same as the methods in which the pixel groups are driven and the correlations between the pixel groups and the common subpixel in FIGS. 7 through 20.

As illustrated in FIG. 21, first, second, third, and fourth pixel groups PG1, PG2, PG3, and PG4 may share a first common subpixel CP. For example, the first through fourth pixel groups PG1 through PG4 may be arranged to extend radially from the first common subpixel CP.

Each of the first through fourth pixel groups PG1 through PG4 may include at least three auxiliary subpixels. The at least three auxiliary subpixels may be arranged in the order of a first auxiliary subpixel PX1 (first common subpixel CP), a second auxiliary subpixel PX2, and a third auxiliary subpixel PX3.

Virtual polygons may be quadrangles, and a first virtual line segment LS1 of a first virtual polygon PO1 may extend in the x-axis direction, and the first virtual line segment LS1 and the first pixel group PG1 may be arranged to overlap each other in a plan view. There may be at least nine auxiliary subpixels arranged to overlap the first virtual line segment LS1. An auxiliary subpixel located at the center among the at least nine auxiliary subpixels may be a second common subpixel CPb.

First, second, third, and fourth auxiliary pixel groups PGs1, PGs2, PGs3, and PGs4 may share the second common subpixel CPb. For example, the first through fourth auxiliary pixel groups PGs1 through PGs4 may be arranged to extend radially from the second common subpixel CPb.

The first auxiliary pixel group PGs1 and the third auxiliary pixel group PGs3 may be aligned with the first pixel group PG1 in a straight line. For example, the first auxiliary pixel group PGs1 and the third auxiliary pixel group PGs3 may be arranged to overlap the first virtual line segment LS1 in a plan view.

For example, a first virtual curve HL1 may be an arc drawn within the first virtual polygon PO1, based on a first vertex of the first virtual polygon PO1. A second virtual curve HL2 may be an arc drawn outside the first virtual polygon PO1 (or within a second virtual polygon PO2), based on a second vertex of the first virtual polygon PO1. One end of a first virtual line segment LS1 may be the first vertex, and the other end thereof may be the second vertex.

For example, a third virtual curve HL3 may be an arc drawn outside the first virtual polygon PO1 (or within a fourth virtual polygon PO4), based on a third vertex of the first virtual polygon PO1. A fourth virtual curve HL4 may be an arc drawn within the first virtual polygon PO1, based on a fourth vertex of the first virtual polygon PO1.

For example, the second auxiliary pixel group PGs2 may be disposed to overlap the second virtual curve HL2. The fourth auxiliary pixel group PGs4 may be disposed to overlap the first virtual line segment LS1. The first virtual curve HL1 and the second virtual curve HL2 may be connected to each other to form a single wave-shaped curve.

In a plan view, a first transmission portion TA1 may be disposed within the first virtual polygon PO1. The first transmission portion TA1 may include a 1-1 auxiliary transmission portion TA1-1, a 1-2 auxiliary transmission portion TA1-2, and a 1-3 auxiliary transmission portion TA1-3. A 1-1 auxiliary transmission portion TA1-1 surrounded by the first virtual curve HL1 and the first virtual polygon PO1 may be arranged within the first virtual polygon PO1 in a plan view, and a shape of the 1-1 auxiliary penetration portion TA1-1 may have a fan shape in a plan view. A 1-2 auxiliary transmission portion TA1-2 surrounded by the first virtual curve HL1, the fourth virtual curve HL4, and the first virtual polygon PO1 may be disposed within the first virtual polygon PO1 in a plan view.

A 1-3 auxiliary transmission portion TA1-3 surrounded by the fourth virtual curve HL4 and the first virtual polygon PO1 may be arranged within the first virtual polygon PO1 in a plan view, and a shape of the 1-3 auxiliary penetration portion TA1-3 may have a fan shape in a plan view.

A second transmission portion TA2 may be disposed inside the second virtual polygon PO1, a third transmission portion TA3 may be disposed inside a third virtual polygon PO3, and a fourth transmission portion TA4 may be disposed inside the fourth virtual polygon PO4. A shape of the first transmission portion TA1 and a shape of the third transmission portion TA3 may be symmetrical to each other with respect to the first common subpixel CP, and a shape of the second transmission portion TA2 and a shape of the fourth transmission portion TA4 may be symmetrical to each other with respect to the first common subpixel CP.

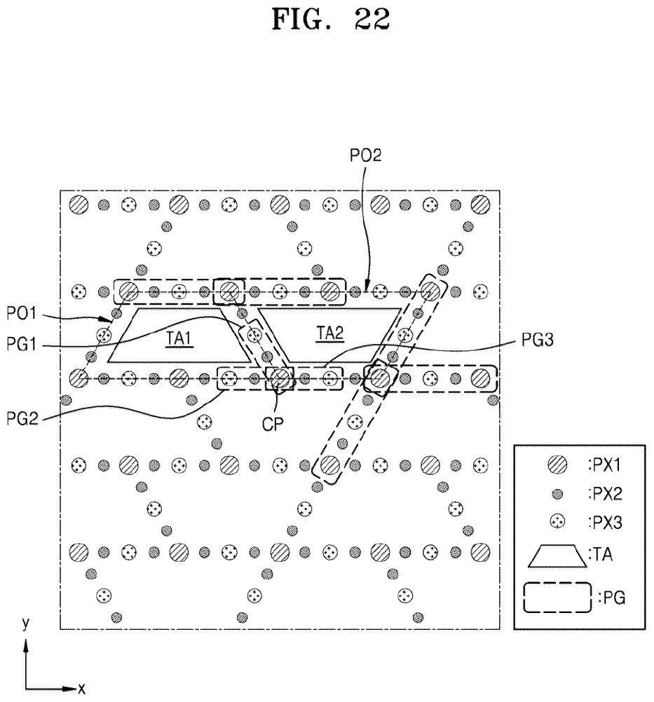

FIG. 22 is a plan view of the display panel 10, schematically showing an auxiliary subpixel pattern of the second display area DA2 of FIG. 1.

For reference, in the description of FIG. 22, the same description as that provided above with reference to FIGS. 1 through 21 may be omitted. A method in which pixel groups are driven and a correlation between the pixel groups and a common subpixel in FIG. 22 may be the same as the methods in which the pixel groups are driven and the correlations between the pixel groups and the common subpixel in FIGS. 7 through 21.

As shown in FIG. 22, each of a plurality of virtual polygons may have a shape of a parallelogram in a plan view. A first virtual polygon PO1 may be adjacent to a second virtual polygon PO2, and a second virtual polygon PO2 may be a shape that is a flipped version of the first virtual polygon PO1. For example, the first virtual polygon PO1 and the second virtual polygon PO2 may share one virtual line segment. When a parallelogram has an upper side (a shorter side among parallel sides), a lower side (a longer side among the parallel sides), and two hypotenuses, a virtual line segment shared by the first virtual polygon PO1 and the second virtual polygon PO2 may be a hypotenuse.

The hypotenuse shared by the first virtual polygon PO1 and the second virtual polygon PO2, and the first pixel group PG1 may be arranged to overlap each other, and the first pixel group PG1 may include at least three auxiliary subpixels. For example, the at least three auxiliary subpixels may be arranged in the order of a first auxiliary subpixel PX1 (first common subpixel CP), a second auxiliary subpixel PX2, and a third auxiliary subpixel PX3. The first pixel groups PG1, a second pixel groups PG2, and a third pixel group PG3 may share the first common subpixel CP.

A lower side of the second virtual polygon PO2 and an upper side of the first virtual polygon PO1 may form a single straight line. The lower side of the second virtual polygon PO2 and the third pixel group PG3 may be arranged to overlap each other, and the third pixel group PG3 may include at least three auxiliary subpixels. Therefore, the second pixel group PG2 and the third pixel group PG3 may be arranged in a straight line.

A first transmission portion TA1 may be disposed within the first virtual polygon PO1 in a plan view, and a planar shape of the first transmission portion TA1 may be a parallelogram. A second transmission portion TA2 may be disposed within the second virtual polygon PO2 in a plan view, and a planar shape of the second transmission portion TA2 may be a parallelogram. The shape of the second transmission portion TA2 may be a flipped version of the shape of the first transmission portion TA1.

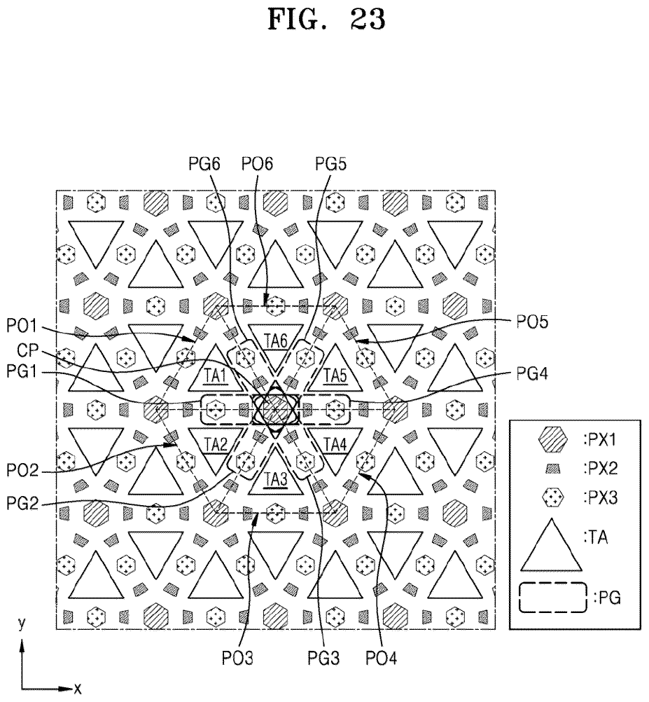

FIG. 23 is a plan view of the display panel 10, schematically showing an auxiliary subpixel pattern of the second display area DA2 of FIG. 1.

For reference, in the description of FIG. 23, the same description as that provided above with reference to FIGS. 1 through 22 may be omitted. A method in which pixel groups are driven and a correlation between the pixel groups and a common subpixel in FIG. 23 may be the same as the methods in which the pixel groups are driven and the correlations between the pixel groups and the common subpixel in FIGS. 7 through 22.

As shown in FIG. 23, each of a plurality of virtual polygons may have a shape of a triangle in a plan view. A first virtual polygon PO1 may be adjacent to a second virtual polygon PO2. First, second, third, fourth, fifth, and sixth virtual polygons PO1, PO2, PO3, PO4, PO5, and PO6 may share one intersection.

For example, the first virtual polygon PO1 and the second virtual polygon PO2 may share one virtual line segment. A first pixel group PG1 may be disposed to overlap a virtual line segment shared by the first virtual polygon PO1 and the second virtual polygon PO2. As such, each of the second through sixth pixel groups PG2 through PG6 may be arranged to overlap a virtual line segment shared by the virtual polygons.

The first through sixth pixel groups PG1 through PG6 may be arranged around a first common subpixel CP, and may share the first common subpixel CP. Each of the first through sixth pixel groups PG1 through PG6 may include at least three auxiliary subpixels.

A transmission portion may be disposed within each of the first through sixth virtual polygons PO1 through PO6. For example, a first transmission portion TA1 may be disposed within the first virtual polygon PO1, a second transmission portion TA2 may be disposed within the second virtual polygon PO2, a third transmission portion TA3 may be disposed within the third virtual polygon PO3, a fourth transmission portion TA4 may be disposed within the fourth virtual polygon PO4, a fifth transmission portion TA5 may be disposed within the fifth virtual polygon PO5, and a sixth transmission portion TA6 may be disposed within the sixth virtual polygon PO6.

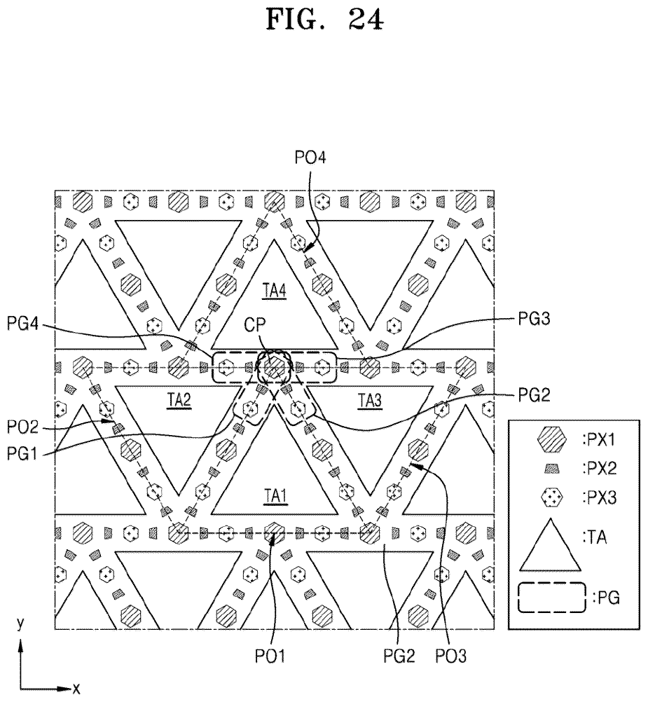

FIG. 24 is a plan view of the display panel 10, schematically showing an auxiliary subpixel pattern of the second display area DA2 of FIG. 1.

For reference, in the description of FIG. 24, the same description as that provided above with reference to FIGS. 1 through 23 may be omitted. A method in which pixel groups are driven and a correlation between the pixel groups and a common subpixel in FIG. 24 may be the same as the methods in which the pixel groups are driven and the correlations between the pixel groups and the common subpixel in FIGS. 7 through 23.

As shown in FIG. 24, each of a plurality of virtual polygons may have a shape of a triangle in a plan view. Respective planar shapes of the first through fourth virtual polygons PO1 through PO4 may be triangles. The first virtual polygon PO1 may be adjacent to the second virtual polygon PO2. The first through third virtual polygons PO1 through PO3 may share one intersection.

For example, the first virtual polygon PO1 and the second virtual polygon PO2 may share one virtual line segment. A first pixel group PG1 may be disposed to overlap the virtual line segment shared by the first virtual polygon PO1 and the second virtual polygon PO2. As such, each of the second through fourth pixel groups PG2 through PG4 may be arranged to overlap a virtual line segment shared by the virtual polygons.

The first through fourth pixel groups PG1 through PG4 may be arranged around a first common subpixel CP, and may share the first common subpixel CP. Each of the first through fourth pixel groups PG1 through PG4 may include at least three auxiliary subpixels. The at least three auxiliary subpixels may be arranged in the order of a first auxiliary subpixel PX1 (first common subpixel CP), a second auxiliary subpixel PX2, and a third auxiliary subpixel PX3.

For example, a transmission portion having a triangular shape may be disposed within each of the first through fourth virtual polygons PO1 through PO4. For example, a first transmission portion TA1 may be disposed inside the first virtual polygon PO1, a second transmission portion TA2 may be disposed inside the second virtual polygon PO2, a third transmission portion TA3 may be disposed inside the third virtual polygon PO3, and a fourth transmission portion TA4 may be disposed inside the fourth virtual polygon PO4.

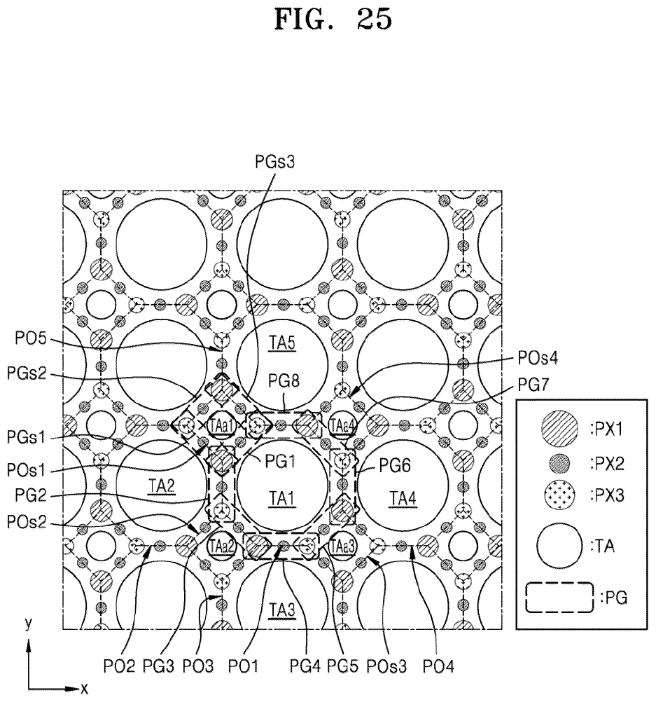

FIG. 25 is a plan view of the display panel 10, schematically showing an auxiliary subpixel pattern of the second display area DA2 of FIG. 1.

For reference, in the description of FIG. 25, the same description as that provided above with reference to FIGS. 1 through 24 may be omitted. A method in which pixel groups are driven and a correlation between the pixel groups and a common subpixel in FIG. 25 may be the same as the methods in which the pixel groups are driven and the correlations between the pixel groups and the common subpixel in FIGS. 7 through 24.

As illustrated in FIG. 25, a plurality of virtual polygons may be classified into a first type having an octagonal shape and a second type having a quadrangular shape. The plurality of virtual polygons may include first, second, third, fourth, and fifth virtual polygons PO1, PO2, PO3, PO4, and PO5 (first type). For example, the first through fifth virtual polygons PO1 through PO5 (first type) may have shapes of octagons in a plan view.

The plurality of virtual polygons may include first, second, third, and fourth auxiliary virtual polygons POs1, POs2, POs3, and POs4 (second type). For example, the first through fourth auxiliary virtual polygons POs1 through POs4 (second type) may have shapes of quadrangles in a plan view.

For example, the first virtual polygon PO1 and the second virtual polygon PO2 may share one virtual line segment. A second pixel group PG2 may be disposed to overlap the one virtual line segment shared by the first virtual polygon PO1 and the second virtual polygon PO2. As such, each of first, third, fourth, fifth, sixth, seventh, and eighth pixel groups PG1, PG3, PG4, PG5, PG6, PG7, and PG8 may be arranged to overlap a virtual line segment shared by the virtual polygons.

For example, line segments forming an auxiliary virtual polygon may be line segments of virtual polygons that surround an auxiliary virtual polygon.

For example, the first auxiliary virtual polygon POs1 and the first virtual polygon PO1 may share one virtual line segment. The first pixel group PG1 may be disposed to overlap the one virtual line segment shared by first auxiliary virtual polygon POs1 and the first virtual polygon PO1.

For example, the first virtual polygon PO1 and each of auxiliary virtual polygons around the first virtual polygon PO1 may share one virtual line segment. The line segments shared by the first virtual polygon PO1 and its surrounding auxiliary virtual polygons, and the first pixel group PG1, the third pixel group PG3, the fifth pixel group PG5, and the seventh pixel group PG7 may be arranged to overlap each other.

For example, the first virtual polygon PO1 and the second virtual polygon PO2 may share one virtual line segment. The second pixel group PG2 may be disposed to overlap the one virtual line segment shared by the first virtual polygon PO1 and the second virtual polygon PO2.

For example, the first virtual polygon PO1 and the third virtual polygon PO3 may share one virtual line segment. The fourth pixel group PG4 may be disposed to overlap the one virtual line segment shared by the first virtual polygon PO1 and the third virtual polygon P03.

For example, the first virtual polygon PO1 and the fourth virtual polygon PO4 may share one virtual line segment. The sixth pixel group PG6 may be disposed to overlap the one virtual line segment shared by the first virtual polygon PO1 and the fourth virtual polygon P04.

For example, the first virtual polygon PO1 and the fifth virtual polygon PO5 may share one virtual line segment. The eighth pixel group PG8 may be disposed to overlap the one virtual line segment shared by the first virtual polygon PO1 and the fifth virtual polygon P05.

For example, each of the first through eighth pixel groups PG1 through PG8 may include at least three auxiliary subpixels. The first pixel group PG1 may share one auxiliary subpixel with the second pixel group PG2, and may share one auxiliary subpixel with the eighth pixel group PG8. As such, one pixel group among the first through eighth pixel groups PG1 through PG8 may include auxiliary subpixels shared with other pixel groups adjacent to the one pixel group.

For example, pixel groups arranged to overlap the first auxiliary virtual polygon POs1 may be the first pixel group PG1, the first auxiliary pixel group PGs1, the second auxiliary pixel group PGs2, and the third auxiliary pixel group PGs3. The first auxiliary pixel group PGs1 may be one of the pixel groups arranged to overlap the second virtual polygon PO2, and the third auxiliary pixel group PGs3 may be one of the pixel groups arranged to overlap the fifth virtual polygon PO5. The second auxiliary pixel group PGs2 may also be one of the pixel groups arranged to overlap another virtual polygon.

Transmission portions may be arranged within the first through fifth virtual polygons PO1 through PO5, respectively. For example, a first transmission portion TA1 may be disposed within the first virtual polygon PO1 in a plan view, and a shape of the first transmission portion TA1 may be circular or octagonal in a plan view. For example, a second transmission portion TA2 may be disposed within the second virtual polygon PO2 in a plan view, and a shape of the second transmission portion TA2 may be circular or octagonal in a plan view. For example, a third transmission portion TA3 may be disposed within the third virtual polygon PO3 in a plan view, and a shape of the third transmission portion TA3 may be circular or octagonal in a plan view. For example, a fourth transmission portion TA4 may be disposed within the fourth virtual polygon PO4 in a plan view, and a shape of the fourth transmission portion TA4 may be circular or octagonal in a plan view. For example, a fifth transmission portion TA5 may be disposed within the fifth virtual polygon PO5 in a plan view, and a shape of the fifth transmission portion TA5 may be circular or octagonal in a plan view.

Auxiliary transmission portions may be arranged within the first through fourth auxiliary virtual polygons POs1 through POs4, respectively. Respective planar shapes of the auxiliary transmission portions may be circular or octagonal. For example, in a plan view, a first auxiliary transmission portion TAa1 may be disposed inside the first auxiliary virtual polygon POs1, a second auxiliary transmission portion TAa2 may be disposed inside the second auxiliary virtual polygon POs2, a third auxiliary transmission portion TAa3 may be disposed inside the third auxiliary virtual polygon POs3, and a fourth auxiliary transmission portion TAa4 may be disposed inside the fourth auxiliary virtual polygon POs4.

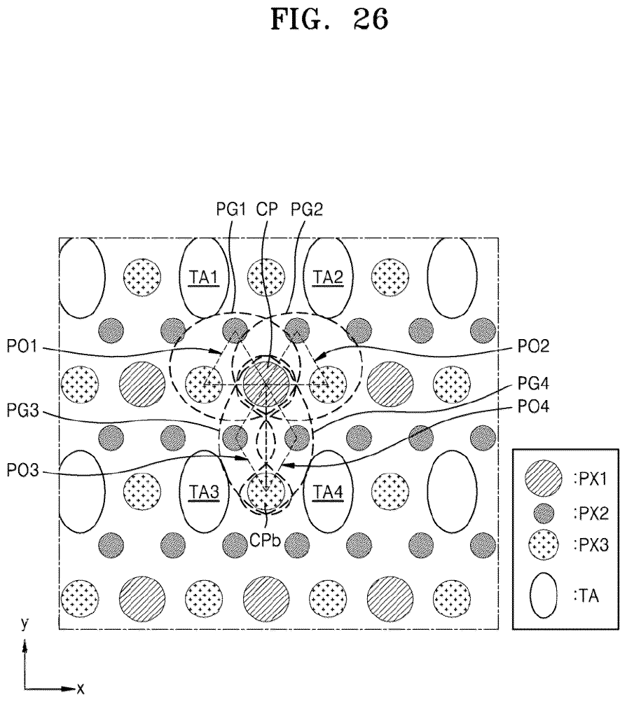

FIG. 26 is a plan view of the display panel 10, schematically showing an auxiliary subpixel pattern of the second display area DA2 of FIG. 1.

For reference, in the description of FIG. 26, the same description as that provided above with reference to FIGS. 1 through 25 may be omitted. A method in which pixel groups are driven and a correlation between the pixel groups and a common subpixel in FIG. 26 may be the same as the methods in which the pixel groups are driven and the correlations between the pixel groups and the common subpixel in FIGS. 7 through 25.

As illustrated in FIG. 26, the first virtual polygon PO1 and the second virtual polygon PO2 may be triangles each having three sides having approximately similar lengths. The first virtual polygon PO1 and the second virtual polygon PO2 may share one point, and may not shore any line segment.

The third virtual polygon PO3 and the fourth virtual polygon PO4 may be triangles each of which two sides have approximately similar lengths. The third virtual polygon PO3 and the fourth virtual polygon PO4 may share a longest side. The first through fourth virtual polygons PO1 through PO4 may share one point.

Three auxiliary subpixels arranged to overlap the first virtual polygon PO1 may be a first pixel group PG1. The three auxiliary subpixels arranged to overlap the first virtual polygon PO1 may be arranged to overlap vertexes constituting the first virtual polygon PO1, respectively.

Three auxiliary subpixels arranged to overlap the second virtual polygon PO2 may be a second pixel group PG2. The three auxiliary subpixels arranged to overlap the second virtual polygon PO2 may be arranged to overlap vertexes constituting the second virtual polygon PO2, respectively.

Three auxiliary subpixels arranged to overlap the third virtual polygon PO3 may be a third pixel group PG3. The three auxiliary subpixels arranged to overlap the third virtual polygon PO3 may be arranged to overlap vertexes constituting the third virtual polygon PO3, respectively.

Three auxiliary subpixels arranged to overlap the fourth virtual polygon PO4 may be a fourth pixel group PG4. The three auxiliary subpixels arranged to overlap the fourth virtual polygon PO4 may be arranged to overlap vertexes constituting the fourth virtual polygon PO4, respectively.

The first through fourth pixel groups PG1 through PG4 may share a first common subpixel CP. The first and second pixel groups PG1 and PG2 may share only the first common subpixel CP. The third pixel group PG3 and the fourth pixel group PG4 may share the first common subpixel CPa and a second common subpixel CPb.

Thus, when the first through fourth pixel groups PG1 through PG4 are turned on, the first common subpixel CP may be driven so that luminances of at most the first through fourth pixel groups PG1 through PG4 are reflected. The second common subpixel CPb may be driven so that luminances of at most the third and fourth pixel groups PG3 and PG4 are reflected.

A first transmission portion TA1 may be disposed around the first virtual polygon PO1. For example, the shape of the first transmission portion TA1 may be circular or elliptical. A second transmission portion TA2 may be disposed around the second virtual polygon PO2. For example, the shape of the second transmission portion TA2 may be circular or elliptical. A third transmission portion TA3 may be disposed around the third virtual polygon PO3. For example, the shape of the third transmission portion TA3 may be circular or elliptical. A fourth transmission portion TA4 may be disposed around the fourth virtual polygon PO4. For example, a shape of the fourth transmission portion TA4 may be circular or elliptical. Each transmission portion may be positioned at a location where one subpixel is omitted.

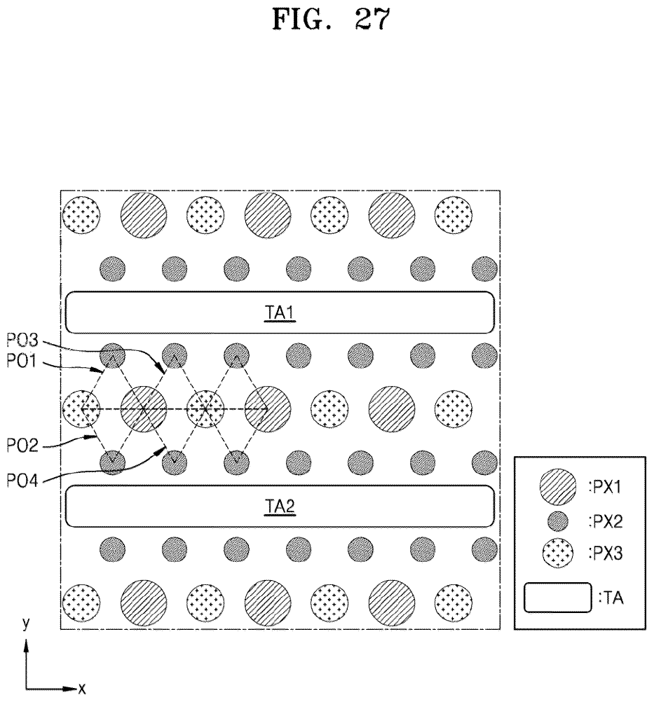

FIG. 27 is a plan view of the display panel 10, schematically showing an auxiliary subpixel pattern of the second display area DA2 of FIG. 1.

For reference, in the description of FIG. 27, the same description as that provided above with reference to FIGS. 1 through 26 may be omitted. A method in which pixel groups are driven and a correlation between the pixel groups and a common subpixel in FIG. 27 may be the same as the methods in which the pixel groups are driven and the correlations between the pixel groups and the common subpixel in FIGS. 7 through 26.

As illustrated in FIG. 27, first, second, third, and fourth virtual polygons PO1, PO2, PO3, and PO4 may be triangles each having three sides having approximately similar lengths. The first through fourth virtual polygons PO1 through PO4 may share one point. The first virtual polygon PO1 and the second virtual polygon PO2 may share one side. The third virtual polygon PO3 and the fourth virtual polygon PO4 may share one side.

Three auxiliary subpixels arranged to overlap the first virtual polygon PO1 may be one pixel group. The three auxiliary subpixels arranged to overlap the first virtual polygon PO1 may be arranged to overlap vertexes constituting the first virtual polygon PO1, respectively.

Three auxiliary subpixels arranged to overlap the second virtual polygon PO2 may be one pixel group. The three auxiliary subpixels arranged to overlap the second virtual polygon PO2 may be arranged to overlap vertexes constituting the second virtual polygon PO2, respectively.

Three auxiliary subpixels arranged to overlap the third virtual polygon PO3 may be one pixel group. The three auxiliary subpixels arranged to overlap the third virtual polygon PO3 may be arranged to overlap vertexes constituting the third virtual polygon PO3, respectively.

Three auxiliary subpixels arranged to overlap the fourth virtual polygon PO4 may be another pixel group. The three auxiliary subpixels arranged to overlap the fourth virtual polygon PO4 may be arranged to overlap vertexes constituting the fourth virtual polygon PO4, respectively.

A pixel group overlapping the first virtual polygon PO1 and a pixel group overlapping the second virtual polygon PO2 may share two auxiliary subpixels. The pixel group overlapping the first virtual polygon PO1, a pixel group overlapping the second virtual polygon PO2, a pixel group overlapping the third virtual polygon PO3, and the pixel group overlapping the fourth virtual polygon PO4 may share one auxiliary subpixel.

The first transmission section TA1 and the second transmission section TA2 may each extend in one direction (e.g., the x-axis direction). The first through fourth virtual polygon PO1 through PO4 described above may be arranged between the first transmission section TA1 and the second transmission section TA2.

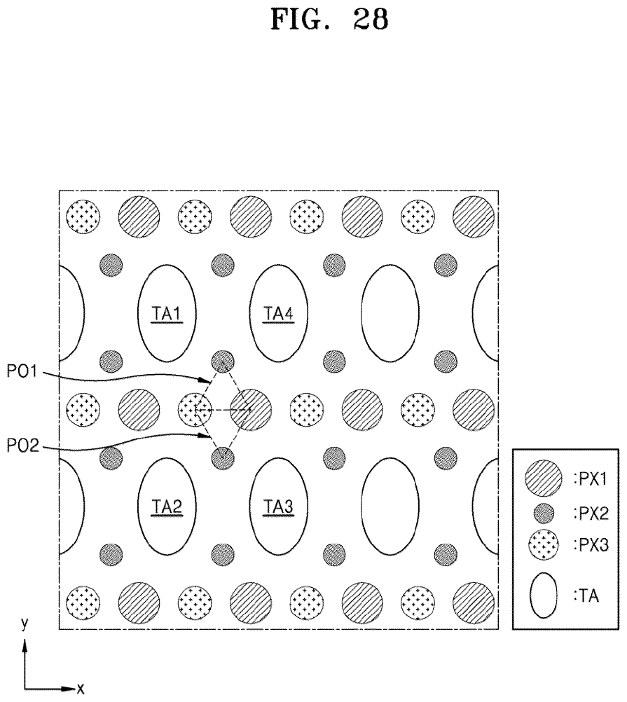

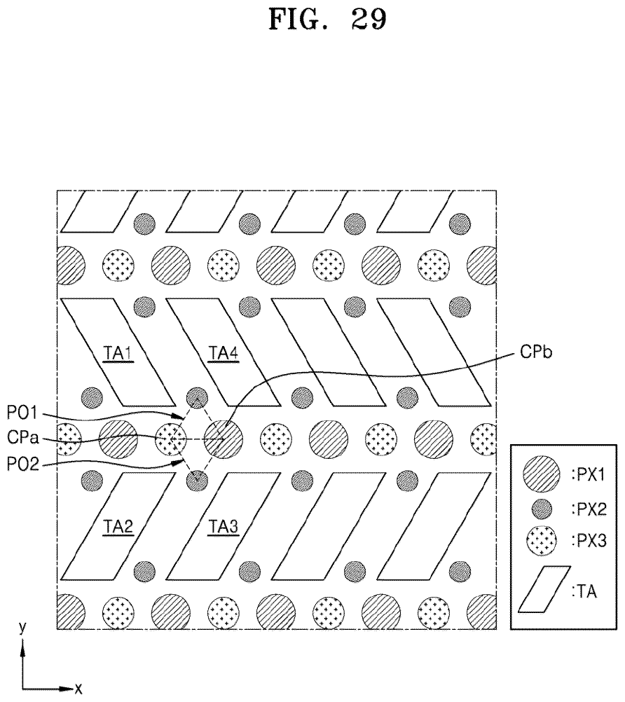

FIGS. 28 and 29 are plan views of the display panel 10, schematically showing auxiliary subpixel patterns of the second display area DA2 of FIG. 1.

For reference, in the descriptions of FIGS. 28 and 29, the same description as that provided above with reference to FIGS. 1 through 27 may be omitted. A method in which pixel groups are driven and a correlation between the pixel groups and a common subpixel in FIGS. 28 and 29 may be the same as the methods in which the pixel groups are driven and the correlations between the pixel groups and the common subpixel in FIGS. 7 through 27.

As illustrated in FIGS. 28 and 29, a first virtual polygon PO1 and a second virtual polygon PO2 may be triangles each having three sides having approximately similar lengths. The first virtual polygon PO1 and the second virtual polygon PO2 may share one side. A pixel group overlapping the first virtual polygon PO1 and a pixel group overlapping the second virtual polygon PO2 may share two auxiliary subpixels.

First, second, third, and fourth transmission portions TA1, TA2, TA3, and TA4 may be arranged around the first virtual polygon PO1 and the second virtual polygon PO2. In FIG. 28, a shape of each of the first through fourth transmission portions TA1 through TA4 may be an ellipse. In FIG. 29, the shape of each of the first through fourth transmission portions TA1 through TA4 may be a parallelogram.

As illustrated in FIGS. 28 and 29, auxiliary subpixels for implementing one dot may be arranged in an RGBG manner. One RGBG set may be disposed side by side with another set in the x-axis direction in the drawings, or may be disposed side by side with another set in the y-axis direction in the drawings. For example, in one RGBG set, two second auxiliary subpixels may be arranged at both ends, and a first auxiliary subpixel and a third auxiliary subpixel may be arranged between the two second auxiliary subpixels. For example, in one RGBG set, two second auxiliary subpixels may be arranged apart from each other in the y-axis direction, and a first auxiliary subpixel and a third auxiliary subpixel may be arranged apart from each other in the x-axis direction. For example, regarding two RGBG sets spaced apart from each other in the y-axis direction, it may be seen that the two second auxiliary subpixels are arranged closest to each other.

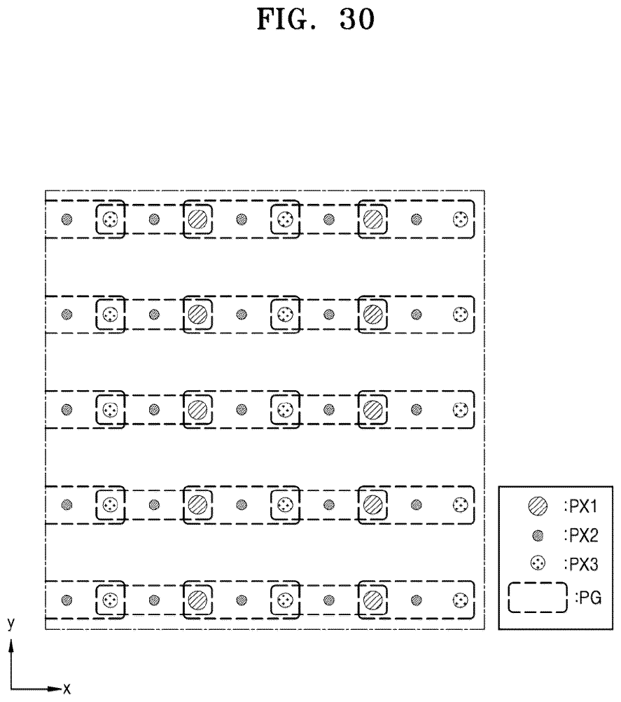

FIGS. 30 through 34 are plan views of the display panel 10, schematically showing auxiliary subpixel patterns of the second display area DA2 of FIG. 1.

For reference, in the descriptions of FIGS. 30 through 34, the same description as that provided above with reference to FIGS. 1 through 29 may be omitted. A method in which pixel groups are driven and a correlation between the pixel groups and a common subpixel in FIGS. 30 through 34 may be the same as the methods in which the pixel groups are driven and the correlations between the pixel groups and the common subpixel in FIGS. 7 through 29.

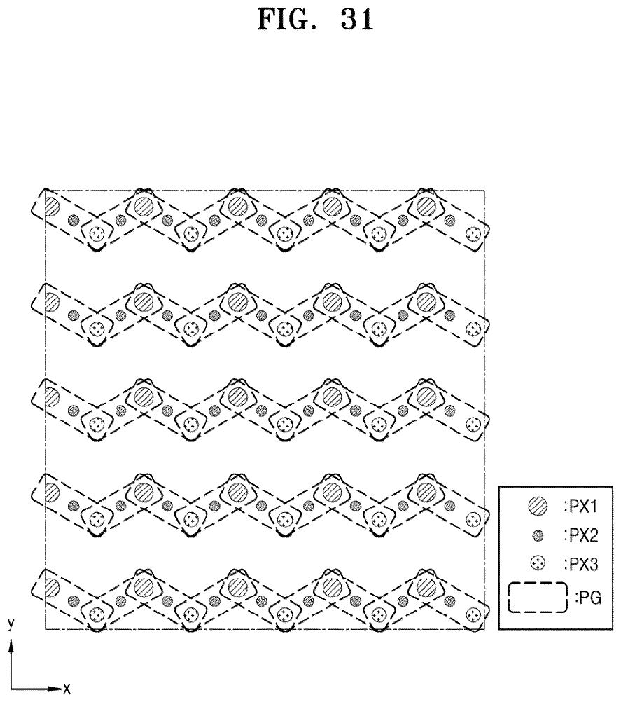

As illustrated in FIGS. 30 through 34, pixel groups may be arranged in the x-axis direction. As shown in FIG. 30, pixel groups may be arranged in one virtual straight line extending in the x-axis direction. Alternatively, as shown in FIGS. 31 through 34, pixel groups may be arranged in a zigzag manner.

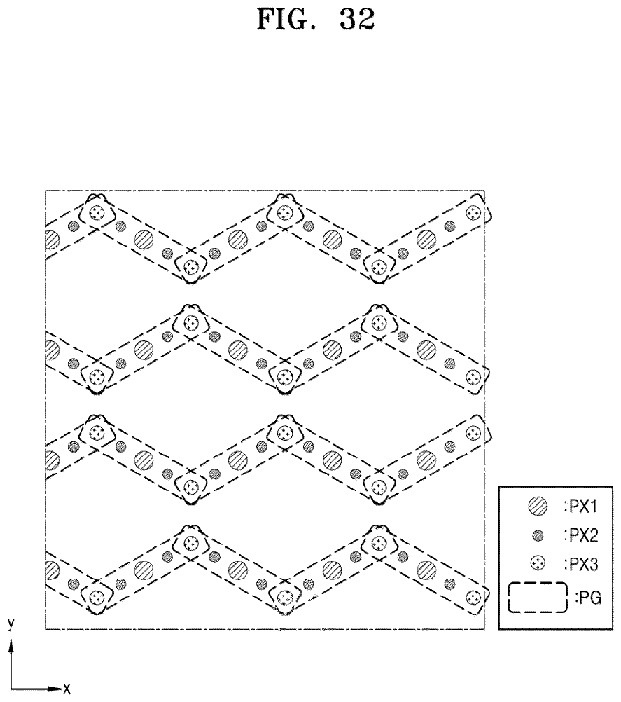

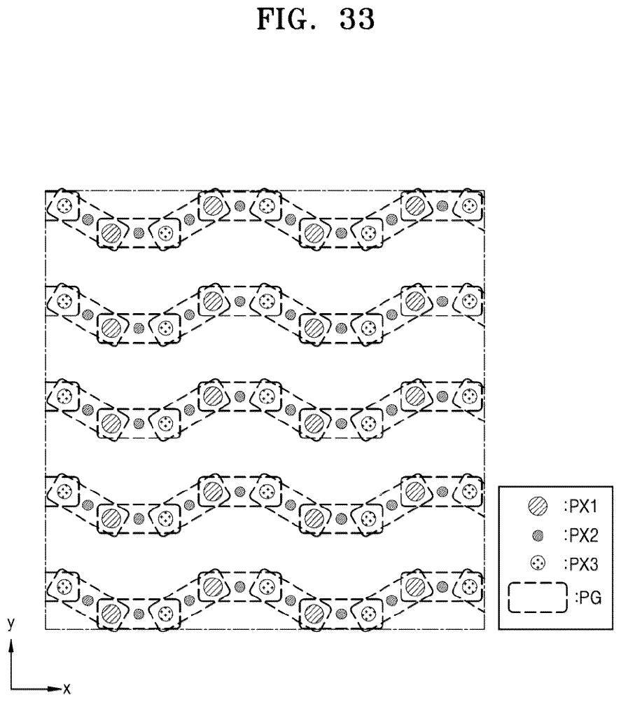

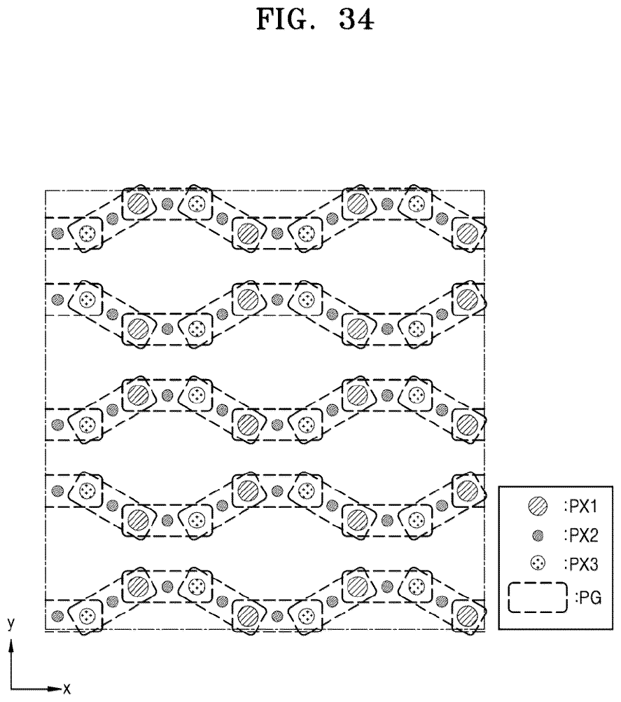

When pixel groups are arranged in a zigzag manner as in FIGS. 31 through 34, the pixel groups may be arranged zigzagged in units of rows (see FIGS. 32 and 34) or arranged not zigzagged in units of rows (FIGS. 31 and 33).

Other pixel groups may be arranged on either side of one pixel group, and adjacent pixel groups may share one auxiliary subpixel. When arranged in a zigzag manner, three auxiliary subpixels may be arranged per zigzag division as in FIGS. 31, 33, and 34, and five auxiliary subpixels may be arranged per zigzag division as in FIG. 32.

As illustrated in FIGS. 30 through 34, a distance between respective second auxiliary subpixels PX2 in two rows may be greater than a distance between second auxiliary subpixels PX2 within the same row.

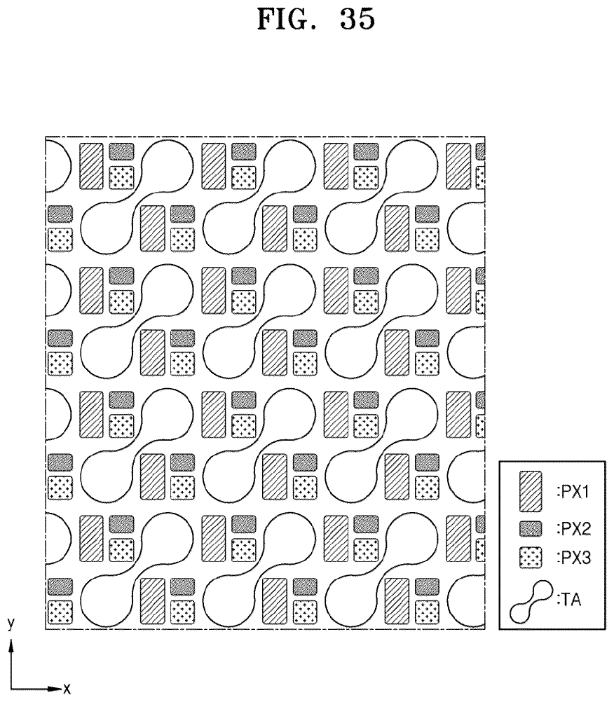

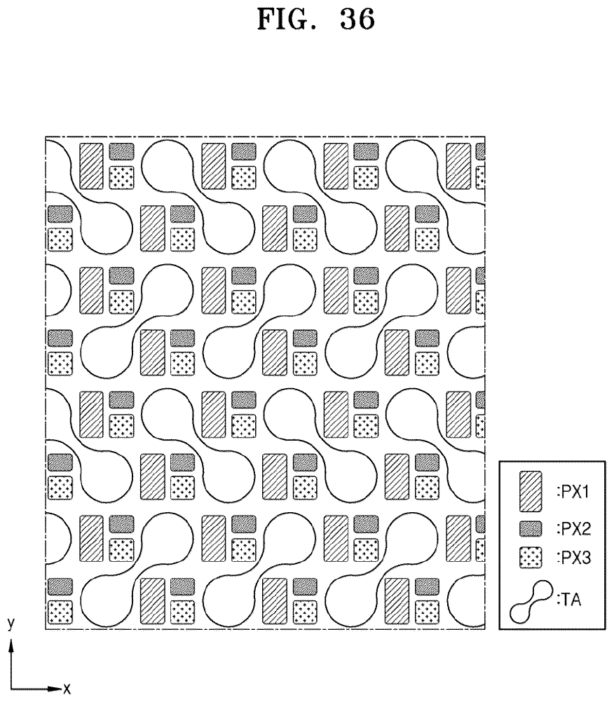

FIGS. 35 and 36 are plan views of the display panel 10, schematically showing auxiliary subpixel patterns of the second display area DA2 of FIG. 1.

For reference, in the descriptions of FIGS. 35 and 36, the same description as that provided above with reference to FIGS. 1 through 34 may be omitted. A method in which pixel groups are driven and a correlation between the pixel groups and a common subpixel in FIGS. 35 and 36 may be the same as the methods in which the pixel groups are driven and the correlations between the pixel groups and the common subpixel in FIGS. 7 through 29.

As illustrated in FIGS. 35 and 36, two transmission portions may be connected to each other to form one transmission portion. As a result, a shape of the transmission portion may be a dumbbell shape in which a center is concave and both ends are rounded.

As shown in FIG. 35, dumbbell-shaped transmission portions may all be arranged in one direction (e.g., in a direction between a y axis and an x axis). The direction in which the dumbbell-shaped transmission portions are arranged may be understood as a direction in which a longer axis of each dumbbell-shaped transmission portion is directed.

Alternatively, as in FIG. 36, the dumbbell-shaped transmission portions may be arranged in different directions row by row. For example, in FIG. 36, the transmission portions in an n-th row may be arranged in a direction between the y axis and the x axis, and transmission portions in an (n+1)th row may be arranged in a direction between the y axis and a-x axis.

By using display panels using pixel array structures according to the above-described embodiments, the following effects may be obtained.

First, the display panels using pixel array structures according to the above-described embodiments may effectively reduce the number of subpixels, by employing a structure in which a plurality of pixel groups share one common subpixel. Accordingly, the area of a transmission portion may be increased, and thus light transmittance may be improved.

Second, the display panels using pixel array structures according to the above-described embodiments may adjust the brightness of a common subpixel in proportion to the number of turn-ons of a pixel group, thereby accurately implementing a desired image even when the number of subpixels is reduced.

Third, in the display panels using pixel array structures according to the above-described embodiments, a transmission portion may be arranged within a virtual polygon, and pixel groups may be arranged to overlap line segments forming the virtual polygon, and thus transmission portions and pixel groups may be efficiently arranged.

Fourth, the display panels using pixel array structures according to the above-described embodiments may change the resolution of a second display area to be lower than the resolution of a first display area, and may also optimize the arrangement of pixel groups to thereby secure visibility.

Fifth, the shapes and arrangement of transmission portions may vary to provide an optimal light transmission area suitable to the characteristics of components.

These are merely exemplary, and thus embodiments are not limited thereto. Various effects may be derived from embodiments by one of ordinary skill in the art.

An electronic device including a display panel 11, according to an embodiment, will now be described in detail based on the above-descriptions.

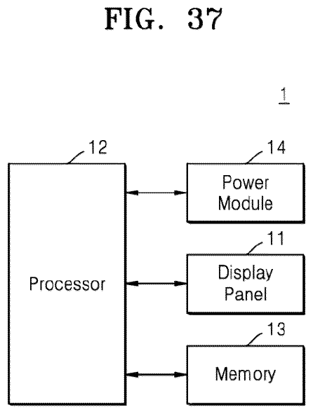

FIG. 37 is a block diagram of an electronic device 1 according to an embodiment.

Referring to FIG. 37, the electronic device 1 may include the display panel 11, a processor 12, a memory 13, and a power module 14.

The processor 12 may include at least one of a central processing unit (CPU), an application processor (AP), a graphics processing unit (GPU), a communication processor (CP), an image signal processor (ISP), and a controller.

The memory 15 may store data information necessary for an operation of the processor 12 or the display panel 11. When the processor 12 executes an application stored in the memory 15, an image data signal and/or an input control signal may be transmitted to the display panel 11, and the display panel 11 may process the received signal and output image information through a display screen.

The power module 14 may include a power supply module, such as a power adapter or a battery device, and a power conversion module that converts power supplied by the power supply module to generate power necessary for an operation of the electronic device 1.

At least one of the components of the electronic device 10 described above may be included in display apparatuses according to the aforementioned embodiments. In addition, some of the individual modules functionally included within a module may be included within a display apparatus, and the others may be provided separately from the display apparatus. For example, the display apparatus may include the display panel 11, and the processor 12, the memory 13, and the power module 14 may be provided in the form of other devices within the electronic device 1 rather than the display apparatus.

The display panel 11 of FIG. 37 may refer to one of the examples of the display panels 11 described above with reference to FIGS. 1 through 36. For the convenience of explanation, other descriptions are omitted, but one of ordinary skill in the art may easily and clearly understand the display panel 11 of FIG. 18 with the descriptions of FIGS. 1 through 36.

According to an embodiment, the electronic device 1 may include the memory 13 storing data information, the processor 12 for generating a data signal and/or a control signal, based on the data information, and the display panel 11 operating based on the data signal and/or the control signal. The display panel 11 may be one of the display panels 10 of FIGS. 1 through 36.

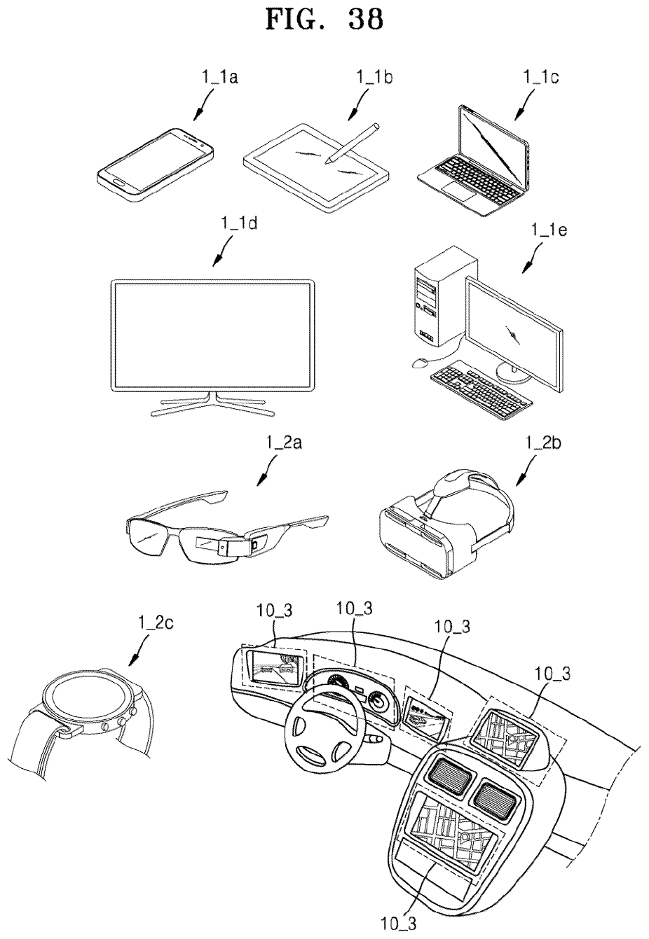

FIG. 38 illustrates schematic diagrams of electronic devices according to various embodiments.

Referring to FIG. 38, various electronic devices to which display apparatuses according to embodiments are applied may include not only image display electronic devices (such as, a smartphone 1_1a, a tablet PC 1_1b, a laptop 1_1c, a TV 1_1d, and a desk monitor 1_1e), but also wearable electronic devices including display modules (such as, smart glasses 1_2a, a head mounted display 1_2b, and a smart watch 1_2c, and vehicle electronic devices 10_3 including display modules (such as, a center information display (CID) disposed on an instrument panel, center fascia, or dashboard of automobiles, and a room mirror display).

According to an embodiment as described above, a display panel having an efficient pixel array structure, and an electronic device including the display panel may be implemented. Of course, the scope of the disclosure is not limited to these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel including a plurality of subpixels arranged on a substrate, the display panel comprising:
a first pixel group driven to correspond to a first dot on a screen, the first pixel group including a first common subpixel;
a second pixel group driven to correspond to a second dot on the screen, the second pixel group sharing the first common subpixel with the first pixel group;
a third pixel group driven to correspond to a third dot on the screen, the third pixel group sharing the first common subpixel with the first pixel group and the second pixel group; and
a first transmission portion surrounded by the first through third pixel groups,
wherein
the first through third pixel groups are arranged to extend radially from the first common subpixel,
the first pixel group and the second pixel group are arranged to overlap a first virtual polygon,
the third pixel group is disposed to overlap a second virtual polygon adjacent to the first virtual polygon, and
the first transmission portion is disposed within the first virtual polygon.

2. The display panel of claim 1, wherein, when the first pixel group is turned on, the first common subpixel emits light based on a first control command for controlling the first pixel group.

3. The display panel of claim 1, wherein, when the first pixel group and the second pixel group are turned on, the first common subpixel emits light, based on a first control command for controlling the first pixel group and a second control command for controlling the second pixel group.

4. The display panel of claim 1, wherein, when the first through third pixel groups are turned on, the first common subpixel emits light, based on a first control command for controlling the first pixel group, a second control command for controlling the second pixel group, and a third control command for controlling the third pixel group.

5. The display panel of claim 1, wherein
the first pixel group includes a first auxiliary subpixel that generates light of a first wavelength, a second auxiliary subpixel that generates light of a second wavelength, and a third auxiliary subpixel that generates light of a third wavelength, and the first common subpixel is the first auxiliary subpixel, and
in a plan view, an area of the first auxiliary subpixel is greater than an area of the second auxiliary subpixel and an area of the third auxiliary subpixel, and the area of the second auxiliary subpixel is less than the area of the third auxiliary subpixel.

6. The display panel of claim 5, wherein,
in a plan view, the first auxiliary subpixel and the third auxiliary subpixel are polygonal,
the second auxiliary subpixel is a trapezoid having an upper side and a lower side longer than the upper side, and
the upper side is disposed to face the third auxiliary subpixel, and the upper side is disposed to face the first auxiliary subpixel.

7. The display panel of claim 5, wherein a center of gravity of each of the first through third auxiliary subpixels is disposed to overlap a virtual line segment that forms the first virtual polygon.

8. The display panel of claim 7, wherein the center of gravity of the second auxiliary subpixel and the center of gravity of the third auxiliary subpixel are arranged to overlap vertexes of the first virtual polygon.

9. A display panel including a plurality of subpixels arranged on a substrate, the display panel comprising:
a first pixel group driven to correspond to a first dot on a screen, disposed to overlap a first virtual polygon, and including a first common subpixel;
a second pixel group driven to correspond to a second dot on the screen, disposed to overlap the first virtual polygon, and sharing the first common subpixel with the first pixel group;
a third pixel group driven to correspond to a third dot on the screen, disposed to overlap a second virtual polygon adjacent to the first virtual polygon, and sharing the first common subpixel with the first pixel group and the second pixel group;
a fourth pixel group disposed within the first virtual polygon, driven to correspond to a fourth dot on the screen, and including a second common subpixel;
a fifth pixel group disposed within the first virtual polygon, driven to correspond to a fifth dot on the screen, and sharing the second common subpixel; and
a sixth pixel group disposed within the first virtual polygon, driven to correspond to a sixth dot on the screen, and sharing the second common subpixel,
wherein
the first through third pixel groups are arranged to extend radially from the first common subpixel, and
the fourth through sixth pixel groups are arranged to extend radially from the second common subpixel.

10. The display panel of claim 9, further comprising a first transmission portion disposed within the first virtual polygon and surrounded by the first pixel group, the second pixel group, the fourth pixel group, and the fifth pixel group.

11. The display panel of claim 9, wherein, when the first pixel group is turned on, the first common subpixel emits light based on a first control command for controlling the first pixel group.

12. The display panel of claim 9, wherein, when the first pixel group and the second pixel group are turned on, the first common subpixel emits light, based on a first control command for controlling the first pixel group and a second control command for controlling the second pixel group.

13. The display panel of claim 9, wherein, when the first through third pixel groups are turned on, the first common subpixel emits light, based on a first control command for controlling the first pixel group, a second control command for controlling the second pixel group, and a third control command for controlling the third pixel group.

14. The display panel of claim 9, wherein, when the fourth pixel group is turned on, the second common subpixel emits light based on a fourth control command for controlling the fourth pixel group.

15. The display panel of claim 9, wherein, when the fourth pixel group and the fifth pixel group are turned on, the second common subpixel emits light, based on a fourth control command for controlling the fourth pixel group and a fifth control command for controlling the fifth pixel group.

16. The display panel of claim 15, wherein, when the fourth through sixth pixel groups are turned on, the second common subpixel emits light, based on the fourth control command for controlling the fourth pixel group, the fifth control command for controlling the fifth pixel group, and a sixth control command for controlling the sixth pixel group.

17. The display panel of claim 5, wherein
the first pixel group includes a first auxiliary subpixel that generates light of a first wavelength, a second auxiliary subpixel that generates light of a second wavelength, and a third auxiliary subpixel that generates light of a third wavelength, and the first common subpixel is the first auxiliary subpixel, and
in a plan view, an area of the first auxiliary subpixel is greater than an area of the second auxiliary subpixel and an area of the third auxiliary subpixel, and the area of the second auxiliary subpixel is less than the area of the third auxiliary subpixel.

18. The display panel of claim 17, wherein a center of gravity of each of the first through third auxiliary subpixels is disposed to overlap a virtual line segment that forms the first virtual polygon.

19. The display panel of claim 18, wherein the center of gravity of the second auxiliary subpixel and the center of gravity of the third auxiliary subpixel are arranged to overlap vertexes of the first virtual polygon.

20. An electronic device comprising:
a memory storing data information;
a processor configured to generate a data signal and/or a control signal, based on the data information; and
the display panel of claim 1 operating based on the data signal and/or the control signal.
